(19) United States
(12) Patent Application Publication
(10) Pub. No.: US 2025/0095705 A1
(43) Pub. Date: Mar. 20, 2025

(54) MEMORY DEVICE

(71) Applicant: Kioxia Corporation, Tokyo (JP)

(72) Inventor: Naoki MATSUSHITA, Seoul (KR)

(73) Assignee: Kioxia Corporation, Tokyo (JP)

(21) Appl. No.: 18/828,760

(22) Filed: Sep. 9, 2024

(30) Foreign Application Priority Data
Sep. 15, 2023 (JP) 2023-150460

(51) Int. Cl. G11C 11/16; G11C 5/06

(52) U.S. Cl. CPC G11C 11/1655; G11C 5/063; G11C 11/1657

(57) ABSTRACT

According to one embodiment, a memory device includes: a memory cell array including first to ninth areas; first and second column switch circuits; first and second row switch circuits. In a case where a cell in the sixth area is selected, the first and second column switch circuits and the first row switch circuit are activated, and in a case where a cell in the seventh area is selected, the second column switch circuit and the first and second row switch circuits are activated, and in a case where a cell in the eighth area is selected, the first and second column switch circuits and the second row switch circuit are activated, and in a case where a cell in the ninth area is selected, the first column switch circuit and the first and second row switch circuits are activated.

### CROSS-REFERENCE TO RELATED APPLICATIONS

This application is based upon and claims the benefit of priority from prior Japanese Patent Application No. 2023-150460, filed Sep. 15, 2023, the entire contents of which are incorporated herein by reference.

### FIELD

Embodiments described herein relate generally to a memory device.

### BACKGROUND

A memory device using a variable resistance element (for example, a magnetoresistive effect element) as a memory element is known. In order to improve characteristics of a memory device, various techniques related to the memory device have been studied and developed.

### BRIEF DESCRIPTION OF THE DRAWINGS

FIG. 1 is a block diagram illustrating a configuration example of a memory device according to a first embodiment.

FIG. 2 is a circuit diagram illustrating a configuration example of a memory cell array of the memory device according to the first embodiment.

FIG. 3 is a bird's-eye view illustrating a configuration example of the memory cell array of the memory device according to the first embodiment.

FIG. 4 is a cross-sectional view illustrating a configuration example of the memory cell array of the memory device according to the first embodiment.

FIG. 5 is a cross-sectional view illustrating a configuration example of the memory cell array of the memory device according to the first embodiment.

FIG. 6 is a schematic diagram illustrating a configuration example of a memory cell of the memory device according to the first embodiment.

FIG. 7 is a diagram illustrating a circuit configuration near the memory cell array of the memory device according to the first embodiment.

FIG. 8 is a schematic diagram illustrating operation states of a column switch circuit of the memory device according to the first embodiment.

FIG. 9 is a schematic diagram illustrating operation states of a row switch circuit of the memory device according to the first embodiment.

FIG. 10 is a diagram for describing areas in the memory cell array of the memory device according to the first embodiment.

FIG. 11 is a diagram for describing an operation example of the memory device according to the first embodiment.

FIG. 12 is a diagram for describing an operation example of the memory device according to the first embodiment.

FIG. 13 is a diagram for describing an operation example of the memory device according to the first embodiment.

FIG. 14 is a diagram for describing an operation example of the memory device according to the first embodiment.

FIG. 15 is a diagram illustrating characteristics of the memory device according to the first embodiment.

### DETAILED DESCRIPTION

In general, according to one embodiment, a memory device includes a memory cell array including a plurality of bit lines, a plurality of word lines, and a plurality of memory cells respectively connected to one of the plurality of bit lines and one of the plurality of word lines, the memory cell array in which first to ninth areas are set; a first column switch circuit connected to the plurality of bit lines and provided on one end side in a first direction of the memory cell array; a second column switch circuit connected to the plurality of bit lines and provided on the other end side in the first direction of the memory cell array; a first row switch circuit connected to the plurality of word lines and provided on one end side in a second direction of the memory cell array; and a second row switch circuit connected to the plurality of word lines and provided on the other end side in the second direction of the memory cell array, wherein in a case where a memory cell in the first area is selected, the first and second column switch circuits and the first and second row switch circuits are activated, and in a case where a memory cell in the second area is selected, the first column switch circuit and the first row switch circuit are activated, and in a case where a memory cell in the third area is selected, the second column switch circuit and the first row switch circuit are activated, and in a case where a memory cell in the fourth area is selected, the second column switch circuit and the second row switch circuit are activated, and in a case where a memory cell in the fifth area is selected, the first column switch circuit and the second row switch circuit are activated, and in a case where a memory cell in the sixth area is selected, the first and second column switch circuits and the first row switch circuit are activated, and in a case where a memory cell in the seventh area is selected, the second column switch circuit and the first and second row switch circuits are activated, and in a case where a memory cell in the eighth area is selected, the first and second column switch circuits and the second row switch circuit are activated, and in a case where a memory cell in the ninth area is selected, the first column switch circuit and the first and second row switch circuits are activated.

Hereinafter, the present embodiment will be described in detail with reference to the drawings. In the following description, elements having the same function and configuration are denoted by the same reference numerals.

In each of the following embodiments, for a plurality of identical components (for example, circuits, interconnects, various voltages and signals, and the like), numbers/alphabetical characters may be added to the end of the reference numerals for differentiation. In a case where components having reference numerals with numbers/alphabetical characters for differentiation at the end are not necessarily distinguished from each other, a description (a reference number) is used in which the number/alphabetical character at the end is omitted.

### (1) First Embodiment

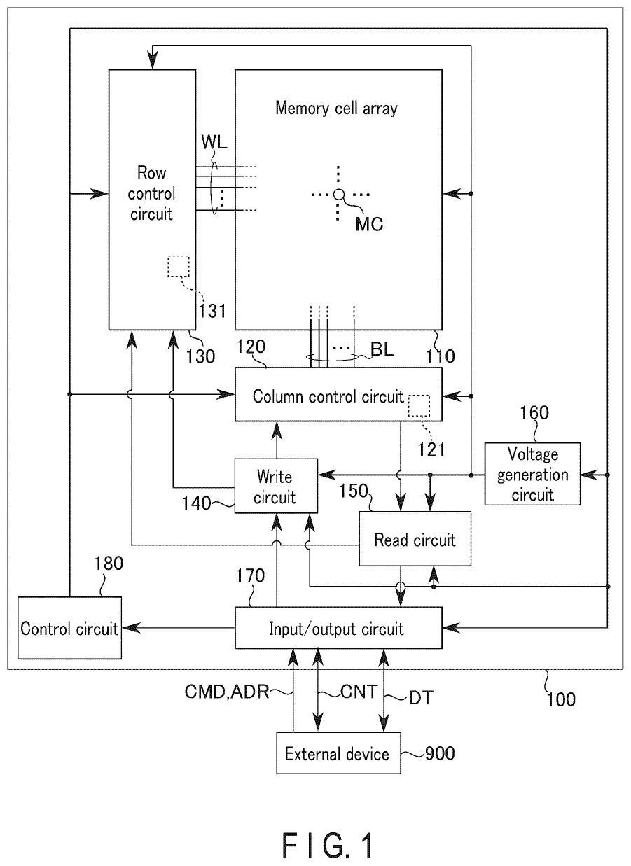

A memory device 100 according to an embodiment will be described with reference to FIGS. 1 to 15.

### (a) Configuration Example

A configuration example of a memory device of the first embodiment will be described with reference to FIGS. 1 to 10.

### (a-1) Overall Configuration

FIG. 1 is a diagram illustrating a configuration example of the memory device 100 of the present embodiment.

As illustrated in FIG. 1, the memory device 100 of the present embodiment is connected to a device (hereinafter referred to as an external device) 900 external to the memory device 100.

The external device 900 sends a command CMD, an address ADR, and a control signal CNT to the memory device 100. Data DT is transferred between the memory device 100 and the external device 900. The external device 900 sends data to be written into the memory device 100 (hereinafter referred to as write data) to the memory device 100 during a write operation. The external device 900 receives data read from the memory device 100 (hereinafter referred to as read data) from the memory device 100 during a read operation.

The memory device 100 of the present embodiment includes a memory cell array 110, a column control circuit 120, a row control circuit 130, a write circuit 140, a read circuit 150, a voltage generation circuit 160, an input/output circuit 170, and a control circuit 180.

The memory cell array 110 includes a plurality of memory cells MC, a plurality of word lines WL, and a plurality of bit lines BL.

The plurality of memory cells MC are associated with a plurality of rows and a plurality of columns in the memory cell array 110. Each memory cell MC is connected to a corresponding one of the plurality of word lines WL. Each memory cell MC is connected to a corresponding one of the plurality of bit lines BL.

The column control circuit 120 controls columns of the memory cell array 110. The column control circuit 120 is connected to the memory cell array 110 via the bit line BL. The column control circuit 120 receives a column address (or a decoding result of the column address) of the memory cell array 110 at the address ADR. The column control circuit 120 controls the plurality of bit lines BL based on the decoding result of the column address. As a result, the column control circuit 120 sets each of the plurality of bit lines BL (the plurality of columns) to a selected state or a non-selected state. Hereinafter, the bit line BL set to the selected state is referred to as a selected bit line BL, and the bit lines BL other than the selected bit line BL are referred to as unselected bit lines BL. The column control circuit 120 includes a plurality of column switch circuits 121. Each column switch circuit 121 controls connection between the selected bit line BL and a global interconnect to be described later.

The row control circuit 130 controls rows of the memory cell array 110. The row control circuit 130 is connected to the memory cell array 110 via the word line WL. The row control circuit 130 receives a row address (or a decoding result of the row address) of the memory cell array 110 at the address ADR. The row control circuit 130 controls the plurality of word lines WL based on the decoding result of the row address. As a result, the row control circuit 130 sets each of the plurality of word lines WL (the plurality of rows) to the selected state or the non-selected state. Hereinafter, the word line WL set to the selected state is referred to as a selected word line WL, and the word lines WL other than the selected word line WL are referred to as unselected word lines WL. The row control circuit 130 includes a plurality of row switch circuits 131. Each row switch circuit 131 controls connection between the selected word line WL and a global interconnect to be described later.

The write circuit 140 writes data to the memory cell MC. The write circuit 140 supplies voltage (or current) for writing data to each of the selected word line WL and the selected bit line BL via the global interconnect. As a result, a certain write voltage (or write current) is supplied to the selected memory cell MC. The write circuit 140 can supply any one of a plurality of write voltages according to the write data to the selected memory cell MC. For example, each of the plurality of write voltages has a polarity (a bias direction) corresponding to the write data. For example, the write circuit 140 includes a write driver (not illustrated), a write sink (not illustrated), and the like.

The read circuit 150 reads data from the memory cell MC. The read circuit 150 amplifies the signal output from the selected memory cell MC to the selected bit line BL. The read circuit 150 determines data in the memory cell MC based on the amplified signal. For example, the read circuit 150 includes a preamplifier (not illustrated), a sense amplifier (not illustrated), a read driver (not illustrated), a read sink (not illustrated), and the like.

The voltage generation circuit 160 generates voltages for various operations of the memory cell array 110 using a power supply voltage provided from the external device 900. For example, the voltage generator 160 generates various voltages used for the write operation. The voltage generation circuit 160 outputs the generated voltage to the write circuit 140. For example, the voltage generation circuit 160 generates various voltages used for the read operation. The voltage generation circuit 160 outputs the generated voltage to the read circuit 150.

The input/output circuit 170 functions as an interface circuit of various signals ADR, CMD, CNT, and DT between the memory device 100 and the external device 900. The input/output circuit 170 transfers the address ADR from the external device 900 to the control circuit 180. The input/output circuit 170 transfers the command CMD from the external device 900 to the control circuit 180. The input/output circuit 170 transfers various control signals CNT between the external device 900 and the control circuit 180. The input/output circuit 170 transfers the write data DT from the external device 900 to the write circuit 140. The input/output circuit 170 transfers the data DT from the read circuit 150 to the external device 900 as read data.

The control circuit (also referred to as a sequencer, a state machine, and an internal controller) 180 decodes the command CMD. The control circuit 180 controls operations of the column control circuit 120, the row control circuit 130, the write circuit 140, the read circuit 150, the voltage generation circuit 160, and the input/output circuit 170 in the memory device 100 based on the decoding result of the command CMD and the control signal CNT. The control circuit 180 decodes the address ADR. The control circuit 180 sends the decoding result of the address ADR to the column control circuit 120, the row control circuit 130, and the like. For example, the control circuit 180 includes a register circuit (not illustrated) that temporarily stores the command CMD and the address ADR. Note that, a register circuit, a circuit (a command decoder) for decoding the command CMD, and a circuit (an address decoder) for decoding the address ADR may be provided in the memory device 100 outside the control circuit 180.

### (a-2) Memory Cell Array

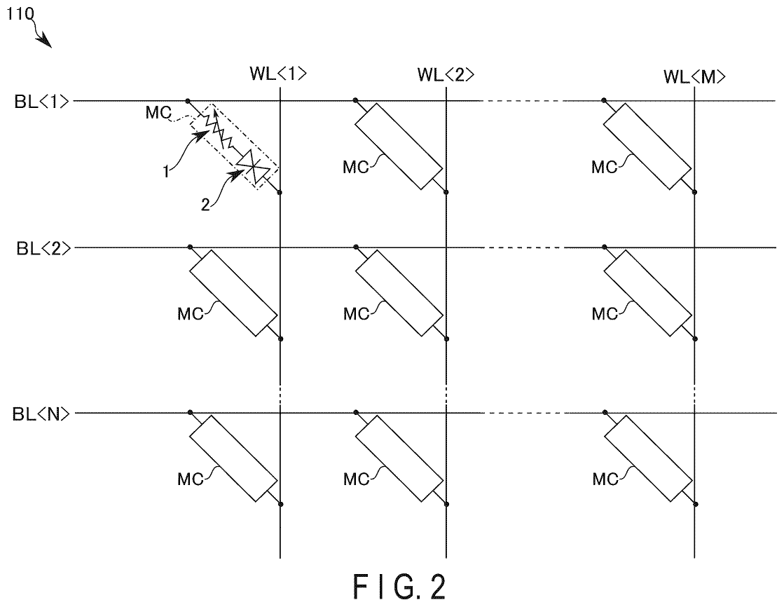

A configuration example of the memory cell array 110 in the memory device 100 of the present embodiment will be described with reference to FIGS. 2 to 5.

FIG. 2 is an equivalent circuit diagram illustrating a configuration example of the memory cell array 110 in the memory device 100 of the present embodiment.

As illustrated in FIG. 2, the plurality of memory cells MC are disposed in a matrix in the memory cell array 110. Each memory cell MC is connected to a corresponding one of the plurality of bit lines BL (BL<1>, BL<2>, . . . , BL<N>) and a corresponding one of the plurality of word lines WL (WL<1>, WL<2>, . . . , WL<M>). M and N are integers of 1 or more.

Each memory cell MC includes a memory element 1 and a switching element 2.

The memory element 1 is, for example, a variable resistance element. A resistance state of the memory element 1 is changed to any one of a plurality of resistance states (for example, a low resistance state and a high resistance state) depending on the supplied voltage (or current). The memory element 1 can store data by associating the resistance state of the element 1 with data (for example, “0” data and “1” data).

The switching element (or also referred to as a selector element or simply a selector) 2 functions as a selection element of the memory cell MC. The switching element 2 has a function of controlling supply of voltage (or current) to the memory element 1 when data is written to the corresponding memory element 1 and when data is read from the corresponding memory element 1.

For example, in a case where a certain voltage applied to a certain memory cell MC is lower than a threshold voltage of the switching element 2 in the memory cell MC, the switching element 2 is set to an OFF state (a high resistance state, a non-conductive state). In this case, the switching element 2 cuts off the voltage (or current) to the memory element 1. In a case where a certain voltage applied to a certain memory cell MC is equal to or higher than the threshold voltage of the switching element 2 in the memory cell MC, the switching element 2 is set to an ON state (a low resistance state, a conductive state). In this case, the switching element 2 supplies voltage (or current) to the memory element 1.

The switching element 2 can switch whether to cause the current to flow in the memory cell MC according to the magnitude of the voltage applied to the memory cell MC regardless of the direction in which the current flows in the memory cell MC.

For example, the switching element 2 is a two-terminal type element. In the example of FIG. 2, one end of the switching element 2 is connected to the word line WL. The other end of the switching element 2 is connected to one end of the memory element 1. The other end of the memory element 1 is connected to the bit line BL.

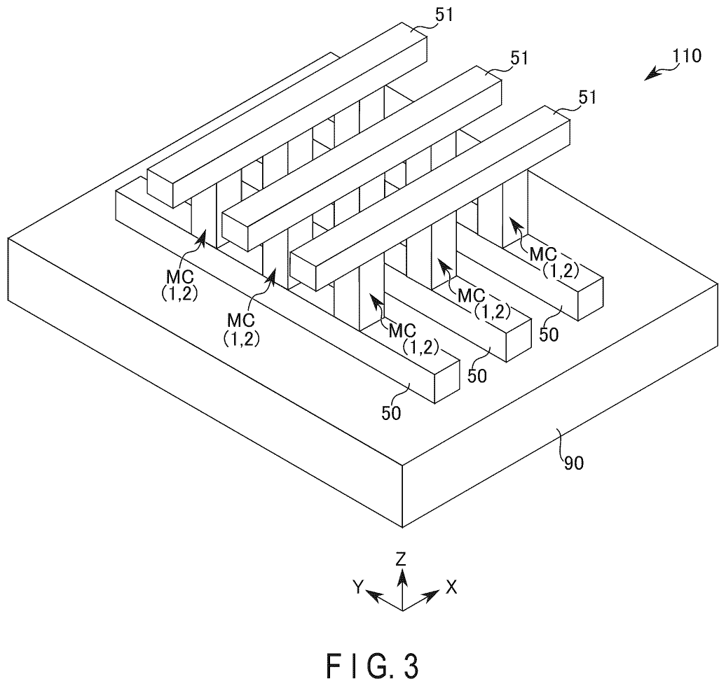

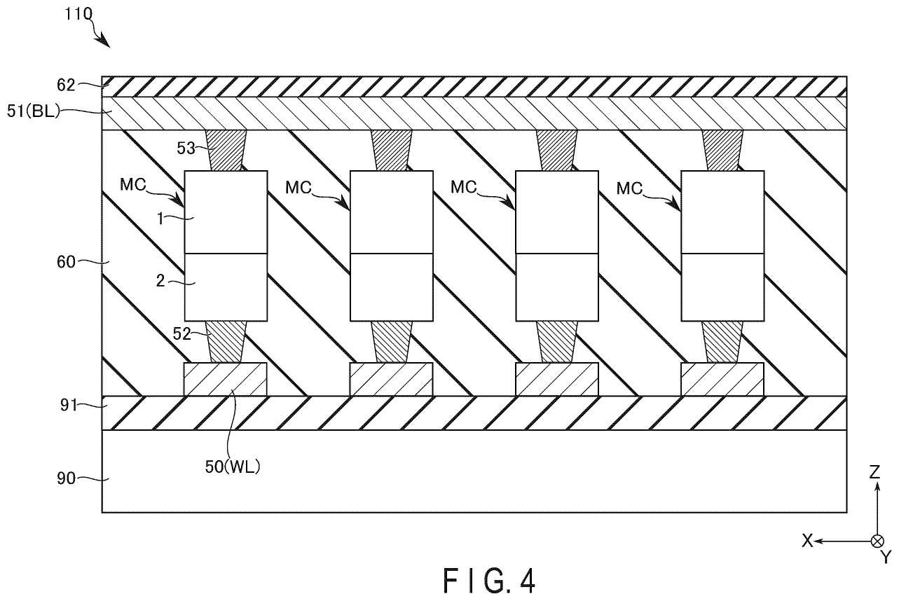

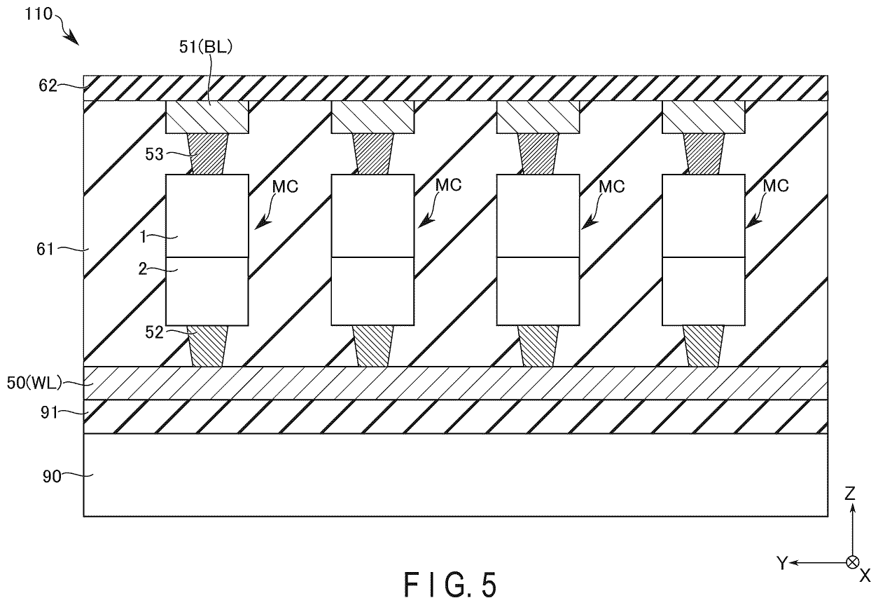

FIGS. 3 to 5 are diagrams for describing a configuration example of the memory cell array 110 in the memory device 100 of the present embodiment. FIG. 3 is a bird's-eye view for describing a configuration example of the memory cell array 110. FIG. 4 is a schematic cross-sectional view illustrating a cross-sectional structure along a first direction (axis) of the memory cell array 110. FIG. 5 is a schematic cross-sectional view illustrating a cross-sectional structure along a second direction (axis) of the memory cell array 110. In the examples of FIGS. 3 to 5, the first direction corresponds to an X direction, and the second direction corresponds to a Y direction.

As illustrated in FIGS. 3 to 5, the memory cell array 110 is provided above an upper surface of a substrate 90. The X direction is a direction parallel to the upper surface of the substrate 90. The Y direction is a direction that is parallel to the upper surface of the substrate 90 and intersects with the X direction. Hereinafter, a plane parallel to the upper surface of the substrate 90 is referred to as an X-Y plane. A direction (an axis) perpendicular to the X-Y plane is a Z direction (a Z axis). A plane parallel to a plane including the X direction and the Z direction is referred to as an X-Z plane. A plane parallel to a plane including the Y direction and the Z direction is referred to as a Y-Z plane.

A plurality of interconnects (a conductive layer) 50 are provided above the upper surface of the substrate 90 via an insulating layer 91 in the Z direction. The plurality of interconnects 50 are arranged along the X direction. Each interconnects 50 extends along the Y direction. The plurality of interconnects 50 function as, for example, the word lines WL.

A plurality of interconnects (a conductive layers) 51 are provided above the plurality of interconnects 50 in the Z direction. The plurality of interconnects 51 are arranged along the Y direction. Each interconnects 51 extends along the X direction. The plurality of interconnects 51 function as, for example, the bit lines BL.

The plurality of memory cells MC are provided between the plurality of interconnects 50 and the plurality of interconnects 51. The plurality of memory cells MC are arranged in a matrix in the X-Y plane.

The plurality of memory cells MC arranged in the Y direction is provided above one interconnect 50. Two memory cells MC arranged in the Y direction are adjacent to each other with a predetermined interval. Each of the plurality of memory cells MC arranged in the Y direction is connected to a common interconnect 50 (the word line WL) via one corresponding contact 52. A plurality of contacts 52 are provided on one interconnect 50.

The plurality of memory cells MC arranged in the X direction is provided below one interconnect 51. Two memory cells MC arranged in the X direction are adjacent to each other with a predetermined interval. Each of the plurality of memory cells MC arranged in the X direction is connected to a common interconnect 51 (the bit line BL) via one corresponding contact 53. A plurality of contacts 53 are provided under one interconnect 51.

For example, in a case where the memory cell array 110 has the circuit configuration of FIG. 2, the switching element 2 is provided below the memory element 1 in the Z direction. The switching element 2 is provided between the memory element 1 and the interconnect 50 (the word line WL). The memory element 1 is provided between the interconnect 51 (the bit line BL) and the switching element 2.

In this way, each memory cell MC is a stacked body of the memory element 1 and the switching element 2. With this memory cell MC, the memory cell array 110 has a stacked configuration.

The memory cell MC may have a tapered cross-sectional shape according to a process (for example, an etching method) used to form the memory cell array 110.

An insulating layer 60 is provided above the substrate 90. The insulating layer 60 covers the memory cell MC, the interconnect 50 and 51, and the contacts 52 and 53. An insulating layer 62 is provided on the insulating layer 60 and the interconnect 51.

FIGS. 4 and 5 illustrate an example in which the insulating layer 91 is provided between the plurality of interconnect 50 and the substrate 90. In a case where the substrate 90 is a semiconductor substrate, one or more field effect transistors (not illustrated) may be provided on a semiconductor region of the upper surface of the substrate 90. The field effect transistor is covered with an insulating layer 91 including a multilayer interconnect structure. The field effect transistor on the substrate 90 is a component of a circuit such as the column control circuit 120. The field effect transistor is connected to the memory cell array 110 via a contact plug (not illustrated) and interconnect (not illustrated) in the insulating layer 91. In this way, a circuit for controlling the operation of the memory cell array 110 may be provided below the memory cell array 110 in the Z direction. Note that, in a case where the substrate 90 is an insulating substrate, the plurality of interconnects 50 may be directly provided on the upper surface of the substrate 90 without the insulating layer 91.

The circuit configuration and structure of the stacked memory cell array 110 are not limited to the examples illustrated in FIGS. 2 to 5. The circuit configuration and structure of the memory cell array 110 can be appropriately modified according to a connection relationship between the memory element 1 and the switching element 2 to the bit line BL and the word line WL. For example, the structure of the memory cell array 110 having the circuit configuration of FIG. 2 is not limited to the examples of FIGS. 3 to 5. For example, the switching element 2 may be provided above the memory element 1 in the Z direction. In this case, the interconnect 50 is used as the bit line BL, and the interconnect 51 is used as the word line WL.

### (a-3) Memory Cell

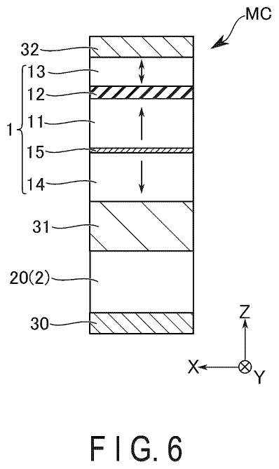

FIG. 6 is a cross-sectional view illustrating a configuration example of the memory cell MC in the memory device 100 of the present embodiment.

As illustrated in FIG. 6, in the memory cell MC which is the stacked body, the memory element 1 and the switching element 2 are arranged in the Z direction. In this example, the memory element 1 is provided on the switching element 2 in the Z direction.

For example, the variable resistance element as the memory element 1 is a magnetoresistive effect element. In this case, the memory device 100 of the present embodiment is a magnetic memory such as a magnetoresistive random access memory (MRAM).

### Configuration Example of Magnetoresistive Effect Element

For example, a magnetoresistive effect element 1 includes at least two magnetic layers 11 and 13 and a non-magnetic layer 12. The non-magnetic layer 12 is provided between the two magnetic layers 11 and 13 in the Z direction. In the example of FIG. 6, a plurality of layers 11, 12, and 13 are arranged in the Z direction in an order of the magnetic layer 11, the non-magnetic layer 12, and the magnetic layer 13 from a side of the word line WL (the interconnect 50) toward a side of the bit line BL (the interconnect 51).

The two magnetic layers 11 and 13 and the non-magnetic layer 12 form a magnetic tunnel junction. Hereinafter, the magnetoresistive effect element 1 including the magnetic tunnel junction is referred to as a magnetic tunnel junction (MTJ) element 1. The non-magnetic layer 12 in the MTJ element 1 is referred to as a tunnel barrier layer.

The magnetic layers 11 and 13 are ferromagnetic layers including, for example, cobalt (Co), iron (Fe) and (or) boron (B), and the like. The magnetic layers 11 and 13 may be a single layer film (for example, an alloy film) or a multilayer film (for example, an artificial lattice film). The tunnel barrier layer 12 is, for example, an insulating layer including magnesium oxide. The tunnel barrier layer 12 may be a single layer film or a multilayer film.

In a case where the MTJ element 1 is a perpendicular magnetization type magnetoresistive effect element, each of the magnetic layers 11 and 13 has perpendicular magnetic anisotropy. The direction of an axis of easy magnetization of each of the magnetic layers 11 and 13 is perpendicular to a layer surface (a film surface) of the magnetic layers 11 and 13. Each of the magnetic layers 11 and 13 has magnetization perpendicular to the layer surfaces of the magnetic layers 11 and 13. The direction of magnetization of each of the magnetic layers 11 and 13 is parallel to an arrangement direction (the Z direction) of the magnetic layers 11 and 13.

Of the two magnetic layers 11 and 13, one magnetic layer has a variable magnetization direction, and the other magnetic layer has an invariable magnetization direction. The MTJ element 1 may have a plurality of resistance states (resistance values) according to a relative relationship (a magnetization arrangement) between the magnetization direction of one magnetic layer and the magnetization direction of the other magnetic layer.

For example, the magnetization direction of the magnetic layer 13 is variable. The magnetization direction of the magnetic layer 11 is invariable (in a fixed state). Hereinafter, the magnetic layer 13 having a variable magnetization direction is referred to as a storage layer. Hereinafter, the magnetic layer 11 in which the magnetization direction is invariable (in a fixed state) is referred to as a reference layer. Note that, the storage layer 13 may also be referred to as a free layer, a magnetization free layer, or a magnetization variable layer. The reference layer 11 may also be referred to as a pin layer, a pinned layer, a magnetization invariant layer, or a magnetization fixed layer.

In the present embodiment, “the magnetization direction of the reference layer (the magnetic layer) is invariable” or “the magnetization direction of the reference layer (the magnetic layer) is in a fixed state” means that in a case where a current or a voltage for changing the magnetization direction of the storage layer 13 is supplied to the MTJ element 1, the magnetization direction of the reference layer 11 does not change by the supplied current or voltage before and after the supply of the current/voltage.

In a case where the magnetization direction of the storage layer 13 is the same as the magnetization direction of the reference layer 11 (in a case where a magnetization arrangement state of the MTJ element 1 is a parallel arrangement state), the resistance state of the MTJ element 1 is a first resistance state. In a case where the magnetization direction of the storage layer 13 is different from the magnetization direction of the reference layer 11 (in a case where the magnetization arrangement state of the MTJ element 1 is an antiparallel arrangement state), the resistance state of the MTJ element 1 is a second resistance state different from the first resistance state. The resistance value of the MTJ element 1 in the second resistance state (the antiparallel arrangement state) is higher than the resistance value of the MTJ element 1 in the first resistance state (the parallel arrangement state).

Hereinafter, for the magnetization arrangement state of the MTJ element 1, the parallel arrangement state is also denoted as a P state, and the antiparallel arrangement state is also denoted as an AP state.

For example, the MTJ element 1 is connected to two electrodes 31 and 32. The magnetic layers 11 and 13 and the tunnel barrier layer 12 are provided between the two electrodes 31 and 32 in the Z direction. The reference layer 11 is provided between the electrode (referred to as an intermediate electrode) 31 and the tunnel barrier layer 12. The storage layer 13 is provided between the electrode (referred to as an upper electrode) 32 and the tunnel barrier layer 12.

For example, a shift cancelling layer 14 may be provided in the MTJ element 1. In this case, the shift cancelling layer 14 is provided between the reference layer 11 and the intermediate electrode 31. The shift cancelling layer 14 is a magnetic layer for mitigating an influence of a stray field of the reference layer 11. In a case where the MTJ element 1 includes the shift cancelling layer 14, a non-magnetic layer 15 is provided between the shift cancelling layer 14 and the reference layer 11. The non-magnetic layer 15 is, for example, a metal layer such as a ruthenium (Ru) layer. The shift cancelling layer 14 is antiferromagnetically coupled to the reference layer 11 via the non-magnetic layer 15. As a result, the stacked body including the reference layer 11 and the shift cancelling layer 14 forms a synthetic antiferromagnetic (SAF) structure. In the SAF structure, the magnetization direction of the shift cancelling layer 14 is opposite to the magnetization direction of the reference layer 11. With the SAF structure, the magnetization direction of the reference layer 11 can be more stably fixed. Note that, a set of the two magnetic layers 11 and 14 and the non-magnetic layer 15 forming the SAF structure may be referred to as a reference layer.

For example, the MTJ element 1 may include at least one of a base layer (not illustrated) and a capping layer (not illustrated). The base layer is provided between the magnetic layer (here, the shift cancelling layer) 14 and the intermediate electrode 31. The base layer is a non-magnetic layer (for example, a conductive layer). The base layer is a layer for improving the characteristics (for example, crystallinity and/or magnetic properties) of the magnetic layer 14 in contact with the base layer. The capping layer is provided between the magnetic layer (here, the storage layer) 13 and the upper electrode 32. The capping layer is a non-magnetic layer (for example, a conductive layer). The capping layer is a layer for improving the characteristics (for example, crystallinity and/or magnetic properties) of the magnetic layer 13 in contact with the capping layer. Note that, each of the base layer and the capping layer may be regarded as a component of the electrodes 31 and 32.

### Configuration Example of Switching Element

As illustrated in FIG. 6, in a case where the switching element 2 is a two-terminal type element, the switching element 2 includes at least one variable resistance layer (also referred to as a switching layer or a selector layer) 20. The variable resistance layer 20 is provided between two electrodes 30 and 31 in the Z direction. The variable resistance layer 20 can take a plurality of resistance states.

The electrode (referred to as a lower electrode) 30 is provided below the variable resistance layer 20 in the Z direction, and the intermediate electrode 31 is provided above the variable resistance layer 20 in the Z direction. For example, the lower electrode 30 is provided between the interconnect 50 and the variable resistance layer 20. The electrode 31 is provided between the variable resistance layer 20 and the MTJ element 1.

The variable resistance layer 20 is connected to the interconnect 50 via the lower electrode 30 and the contact 52. The variable resistance layer 20 is connected to the MTJ element 1 via the intermediate electrode 31.

The resistance state of the variable resistance layer 20 becomes a high resistance state (a non-conduction state) or a low resistance state (a conduction state) according to the voltage applied to the switching element 2 (the memory cell MC). In a case where the resistance state of the variable resistance layer 20 is the high resistance state, the switching element 2 is turned off. In a case where the resistance state of the variable resistance layer 20 is the low resistance state, the switching element 2 is turned on.

In a case where the memory cell MC is set to the selected state, the switching element 2 is turned on, so that the resistance state of the variable resistance layer 20 is a low resistance state. In a case where the memory cell MC is set to the non-selected state, the switching element 2 is turned off, so that the resistance state of the variable resistance layer 20 is a high resistance state.

Note that, according to a material of the variable resistance layer 20, a change in the resistance state of the variable resistance layer 20 may depend on the current (for example, the magnitude of the current) flowing in the switching element 2 (the memory cell MC).

For example, the lower electrode 30 and the upper electrode 32 are conductive layers made of titanium (Ti), tungsten (W), titanium nitride (TiN), tungsten nitride (WN), or the like. The intermediate electrode 31 is a conductive layer made of carbon (C) or carbon nitride (CN).

The memory cell array 110 having the structure of FIGS. 3 to 6 can be formed using well-known techniques.

### (a-4) Configuration Near Memory Cell Array

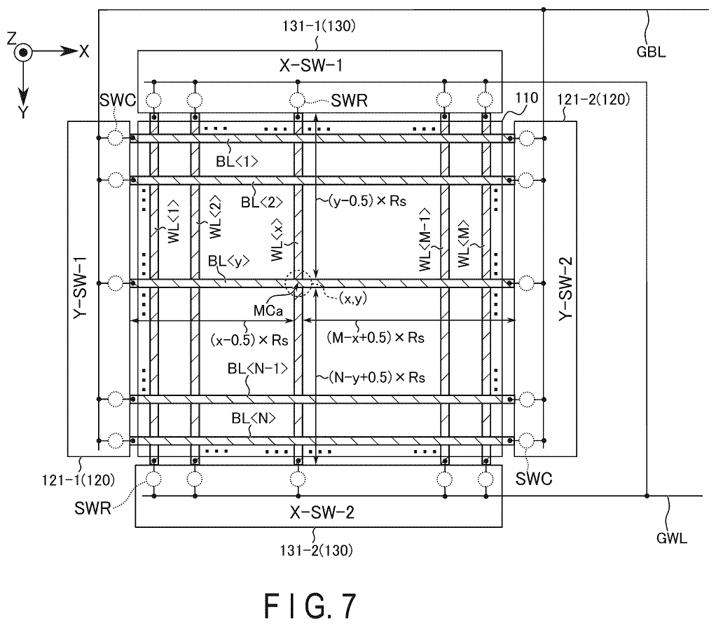

FIG. 7 is a diagram for describing a configuration near the memory cell array 110 of the MRAM100 of the present embodiment.

As illustrated in FIG. 7, the memory cell array 110 has a quadrangular layout when viewed from the Z direction.

M word lines WL<1>, WL<2>, . . . , WL<x> . . . , WL<M-1>, and WL<M> are arranged in the X direction with predetermined intervals within the memory cell array 110. N bit lines BL<1>, BL<2>, . . . , BL<y> . . . , BL<N-1>, BL<N> are arranged in the Y direction with predetermined intervals within the memory cell array 110. The bit line BL is disposed above the word line WL in the Z direction.

For example, a memory cell MCa is disposed at coordinates indicated by (x, y) in the memory cell array 110. The memory cell MCa is provided at a position where the word line WL<x> and the bit line BL<y> intersect. x is an integer of 1 or more and M or less. y is an integer of 1 or more and N or less.

In the present embodiment, the value of “M” is equal to the value of “N”. The interval between the memory cells MC in the X direction is equal to the interval between the memory cells MC in the Y direction. The memory cell array 110 has a square layout (a planar structure) when viewed from the Z direction.

In a case where the plurality of memory cells MC are arranged at predetermined intervals in the X direction, resistance between two memory cells MC adjacent in the X direction has a resistance value of “Rs_x”. When the address of the bit line BL changes by one, interconnect resistance applied to the memory cell MC varies by “Rs_x”. In a case where the plurality of memory cells MC are arranged at predetermined intervals in the Y direction, the resistance between two memory cells MC adjacent in the Y direction has a resistance value of “Rs_y”. When the address of the word line WL changes by one, the interconnect resistance applied to the memory cell MC varies by “Rs_y”.

For example, in the present embodiment, the value of “Rs_x” is equal to the value of “Rs_y”. Hereinafter, the resistance between the memory cells MC is denoted as “Rs”.

In the MRAM 100 of the present embodiment, the column control circuit 120 includes two column switch circuits 121-1 and 121-2.

Among the two column switch circuits 121-1 and 121-2, one column switch circuit 121-1 is provided on one end side in the X direction of the memory cell array 110. Among the two column switch circuits 121-1 and 121-2, the other column switch circuit 121-2 is provided on the other end side in the X direction of the memory cell array 110. The memory cell array 110 is provided between the two column switch circuits 121-1 and 121-2 in the X direction.

The two column switch circuits 121-1 and 121-2 are commonly connected to a plurality of global bit lines GBL. The plurality of global bit lines GBL are connected to the write circuit 140 and the read circuit 150.

Each column switch circuit 121-1 and 121-2 includes a plurality of column switches SWC. The column switch SWC is, for example, a field effect transistor. One end of each column switch SWC is electrically connected to one corresponding bit line BL among the plurality of bit lines BL. The other end of each column switch SWC is electrically connected to one corresponding global bit line GBL among the plurality of global bit lines.

In the column switch circuits 121-1 and 121-2, each column switch SWC is set to the ON state or the OFF state according to the supplied address ADR. In response to on/off of the plurality of column switches SWC in the column switch circuit 121-1 and 121-2, one bit line BL is electrically connected to the corresponding global bit line GBL via the column switch SWC in the ON state.

Here, the interval between the memory cell MC at an end edge in the X direction of the memory cell array 110 and the column switch circuit 121 is set to half a distance between the memory cells MC adjacent in the X direction. Therefore, the resistance between the column switch circuit 121 and the memory cell MC at the end edge in the X direction is “0.5×Rs”.

The interconnect resistance between the memory cell MCa at the coordinates (x, y) and the column switch circuit 121-1 is “(x−0.5)×Rs”. The interconnect resistance between the memory cell MCa at the coordinates (x, y) and the column switch circuit 121-2 is “(M−x+0.5)×Rs”.

In this way, according to the coordinates of the memory cell MCa in the memory cell array 110, a length of the distance to a voltage/current supply source (for example, the write circuit 140 or the read circuit 150) used for various operations of the MRAM 100 in the memory cell MCa changes. As a result, during the operation of the MRAM 100, the magnitude of the interconnect resistance applied to the memory cell MCa changes according to the coordinates of the memory cell MCa.

In the present embodiment, when the read operation and the write operation are performed on the memory cell array 110, both of the two column switch circuits 121-1 and 121-2 or one of the two column switch circuits 121-1 and 121-2 is turned on (activated).

As illustrated in FIG. 7, in the MRAM of the present embodiment, the row control circuit 130 includes two row switch circuits 131-1 and 131-2.

Among the two row switch circuits 131-1 and 131-2, one row switch circuit 131-1 is provided on one end side in the Y direction of the memory cell array 110. Among the two row switch circuits 131-1 and 131-2, the other row switch circuit 131-2 is provided on the other end side in the Y direction of the memory cell array 110. The memory cell array 110 is provided between the two row switch circuits 131-1 and 131-2 in the Y direction.

The two row switch circuits 131-1 and 131-2 are commonly connected to a plurality of global word lines GWL. The plurality of global word lines GWL is connected to the write circuit 140 and the read circuit 150.

Each row switch circuit 131-1 and 131-2 includes a plurality of row switches SWR. The row switch SWR is, for example, a field effect transistor. One end of each row switch SWR is electrically connected to one corresponding word line WL among the plurality of word lines WL. The other end of each row switch SWR is electrically connected to one corresponding global word line GWL among the plurality of global word lines GWL.

In the row switch circuits 131-1 and 131-2, each row switch SWR is set to the ON state or the OFF state according to the supplied address ADR. In response to on/off of the plurality of row switches SWR in the row switch circuits 131-1 and 131-2, one word line WL is electrically connected to the corresponding global word line GWL via the row switch SWR in the ON state.

Here, the interval between the memory cell MC at the end edge in the Y direction of the memory cell array 110 and the row switch circuit 131 is set to half the distance between the memory cells MC adjacent in the Y direction. Therefore, the interconnect resistance between the row switch circuit 131 and the memory cell MC at the end edge in the Y direction is “0.5×Rs”.

The interconnect resistance between the memory cell MCa at the coordinates (x, y) and the row switch circuit 131-1 is “(y−0.5)×Rs”. The interconnect resistance between the memory cell MCa at the coordinates (x, y) and the row switch circuit 131-2 is “(N−y+0.5)×Rs”.

In this way, the magnitude of the interconnect resistance applied to the memory cell MCa changes according to the y coordinate of the memory cell MCa in the memory cell array 110.

In the present embodiment, when the read operation and the write operation are performed on the memory cell array 110, both of the two row switch circuits 131-1 and 131-2 or either one of the two row switch circuits 131-1 and 131-2 is turned on (activated).

In the MRAM 100 of the present embodiment, the operations (on/off states) of the two column switch circuits 121-1 and 121-2 and the operations (on/off states) of the two row switch circuits 131-1 and 131-2 are controlled according to the coordinates of the memory cell MC to be operated in the memory cell array 110. Hereinafter, the memory cell to be operated is referred to as a selected cell.

### (a-5) Relationship Between Operation State of Switch Circuit and Interconnect Resistance

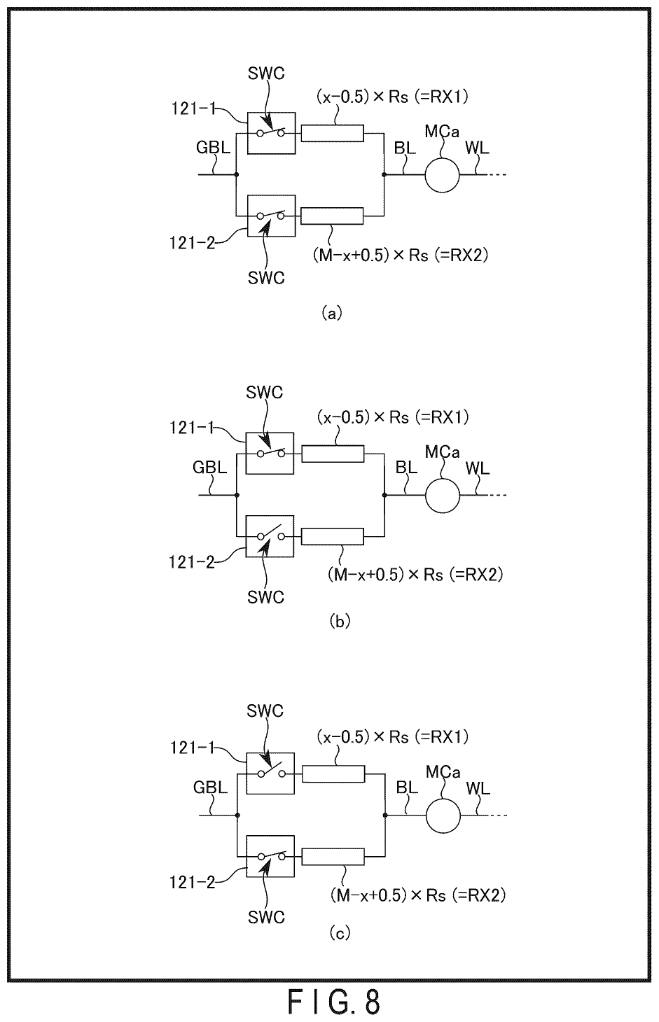

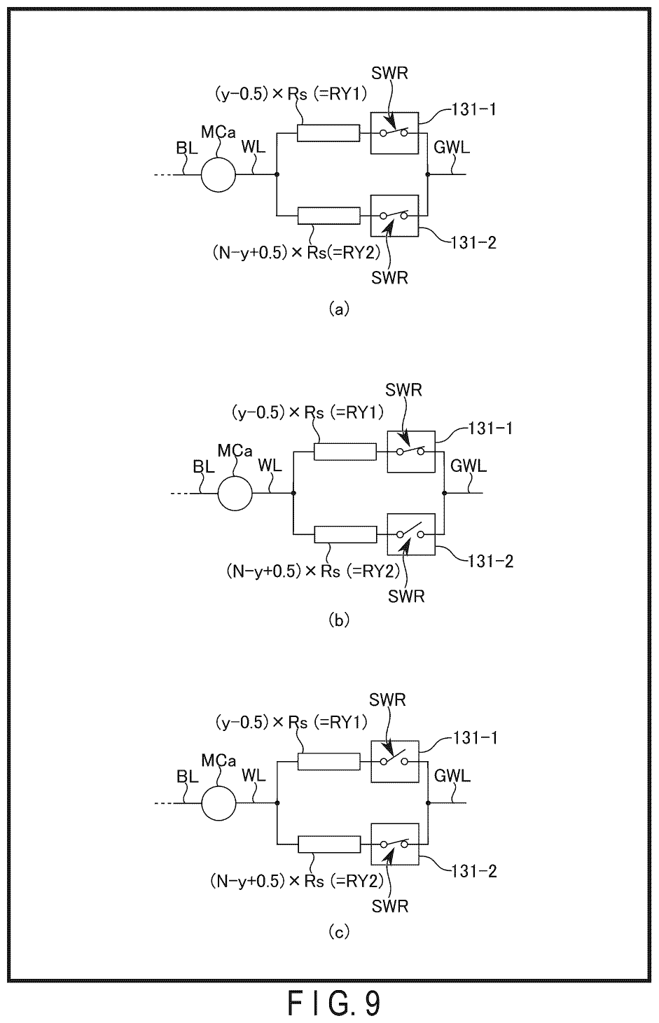

The relationship between the operating states of the column switch circuits 121 and row switch circuits 131 and the interconnect resistance applied to the memory cell MC in the MRAM 100 of the present embodiment will be described with reference to FIGS. 8 and 9.

FIG. 8 is a schematic diagram for describing the relationship between the operating state of the column switch circuit 121 and the interconnect resistance applied to the selected cell MCa in the MRAM 100 of the present embodiment.

As illustrated in FIG. 8, in a case where the selected cell MCa is connected to the global bit line GBL using both or either one of the two column switch circuits 121-1 and 121-2, the magnitude of the interconnect resistance between the memory cell MC and the global bit line GBL changes according to a path formed by the column switch circuit 121 in the ON state.

(a) of FIG. 8 is a diagram schematically illustrating the interconnect resistance between the selected cell MCa and the global bit line GBL in a case where the two column switch circuits 121-1 and 121-2 are set to the ON state (an activated state).

As illustrated in (a) of FIG. 8, the two column switch circuits 121-1 and 121-2 are set to the ON state. A resistance RX1 exists on a connection path between the memory cell MC and the global bit line GBL via the column switch circuit 121-1 in the ON state. A resistance RX2 exists on the connection path between the selected cell MCa and the global bit line GBL via the column switch circuit 121-2 in the ON state.

The resistance RX1 is “(x−0.5)×Rs”. The resistance RX2 is “(M−x+0.5)×Rs”.

In a case where the selected cell MCa is connected to the global bit line GBL by both of the two column switch circuits 121-1 and 121-2, the two resistances RX1 and RX2 are connected in parallel between the memory cell MCa and the global bit line GBL. In this case, the interconnect resistance between the selected cell MCa and the global bit line GBL is “RX1×RX2/(RX1+RX2)”. Therefore, the interconnect resistance of the bit line BL can be expressed as “Rs×(x−0.5)×(M−x+0.5)/M”.

(b) of FIG. 8 is a diagram schematically illustrating the interconnect resistance between the selected cell MCa and the global bit line GBL in a case where only one column switch circuit 121-1 is set to the ON state.

As illustrated in (b) of FIG. 8, the one column switch circuit 121-1 is set to the ON state, and the other column switch circuit 121-2 is set to the OFF state (a deactivated state). Therefore, the resistance RX2 is electrically isolated from the global bit line GBL.

In a case where the selected cell MCa is connected to the global bit line GBL by the one column switch circuit 121-1, the resistance RX1 is connected between the selected cell MCa and the global bit line GBL. In this case, the interconnect resistance between the selected cell MCa and the global bit line GBL can be expressed as “(x−0.5)×Rs”.

(c) of FIG. 8 is a diagram schematically illustrating the interconnect resistance between the selected cell MCa and the global bit line GBL in a case where only the other column switch circuit 121-2 is set to the ON state.

As illustrated in (c) of FIG. 8, the one column switch circuit 121-1 is set to the OFF state, and the other column switch circuit 121-2 is set to the ON state. Therefore, the resistance RX1 is electrically isolated from the global bit line GBL.

In a case where the selected cell MCa is connected to the global bit line GBL by the other column switch circuit 121-2, the resistance RX2 is connected between the selected cell MCa and the global bit line GBL. In this case, the interconnect resistance between the selected cell MCa and the global bit line GBL can be expressed as “(M−x+0.5)×Rs”.

As described with reference to FIG. 8, the operation of the column switch circuit 121 related to a selection of the column of the memory cell array 110 can be controlled in three ways. Accordingly, for the column of the memory cell array 110, any one of three sizes of interconnect resistance is applied to the selected cell MCa according to the operation of the column switch circuit 121.

FIG. 9 is a schematic diagrams for describing the relationship between the operation state of the row switch circuit 131 and the interconnect resistance of the selected cell MCa in the MRAM 100 of the present embodiment.

As illustrated in FIG. 9, in a case where the selected cell MCa is connected to the global word line GWL using both or either one of the two row switch circuits 131-1 and 131-2, the magnitude of the interconnect resistance between the memory cell MC and the global word line GWL changes according to the path formed by the row switch circuit 131 in the ON state.

(a) of FIG. 9 is a diagram schematically illustrating the interconnect resistance between the selected cell MCa and the global word line GWL in a case where the two row switch circuits 131-1 and 131-2 are set to the ON state (the activated state).

As illustrated in (a) of FIG. 9, the two row switch circuits 131-1 and 131-2 are set to the ON state. A resistance RY1 exists on the connection path between the selected cell MCa and the global word line GWL via the row switch circuit 131-1 in the ON state. A resistance RY2 exists on the connection path between the selected cell MCa and the global word line GWL via the row switch circuit 131-2 in the ON state.

The resistance RY1 is “(y−0.5)×Rs”. The resistance RY2 is “(N−y+0.5)×Rs”.

In a case where the selected cell MCa is connected to the global word line GWL by both of the two row switch circuits 131-1 and 131-2, the two resistances RY1 and RY2 are connected in parallel between the selected cell MCa and the global word line GWL. In this case, the interconnect resistance between the selected cell MCa and the global word line GWL is “RY1×RY2/(RY1+RY2)”. Therefore, the interconnect resistance of the word line WL can be expressed as “Rs×(y−0.5)×(M−y+0.5)/N”.

(b) of FIG. 9 is a diagram schematically illustrating the interconnect resistance between the selected cell MCa and the global word line GWL in a case where one row switch circuit 131-1 is set to the ON state.

As illustrated in (b) of FIG. 9, the one row switch circuit 131-1 is set to the ON state, and the other row switch circuit 131-2 is set to the OFF state (the deactivated state). Therefore, the resistance RY2 is electrically isolated from the global word line GWL.

In a case where the selected cell MCa is connected to the global word line GWL by the one row switch circuit 131-1, the resistance RY1 is connected between the selected cell MCa and the global word line GWL. In this case, the interconnect resistance between the selected cell MCa and the global word line GWL can be expressed as “(y−0.5)×Rs”.

(c) of FIG. 9 is a diagram schematically illustrating the interconnect resistance between the selected cell MCa and the global word line GWL in a case where the other row switch circuit 131-2 is set to the ON state.

As illustrated in (c) of FIG. 9, the one row switch circuit 131-1 is set to the OFF state, and the other row switch circuit 131-2 is set to the ON state. Therefore, the resistance RY1 is electrically isolated from the global word line GWL.

In a case where the selected cell MCa is connected to the global word line GWL by the other row switch circuit 131-2, the resistance RY2 is connected between the selected cell MCa and the global word line GWL. In this case, the interconnect resistance between the selected cell MCa and the global word line GWL can be expressed as “(N−y+0.5)×Rs”.

As described with reference to FIG. 9, the operation of the row switch circuit 131 related to the selection of the row of the memory cell array 110 can be controlled in three ways. Accordingly, for the row of the memory cell array 110, any one of three sizes of interconnect resistance is applied to the selected cell MCa according to the operation of the row switch circuit 131.

As illustrated in FIGS. 8 and 9, in the present embodiment, the memory cells MC in the memory cell array 110 can be selected by 3×3 (9) selection methods by controlling the two column switch circuits 121-1 and 121-2 and the two row switch circuits 131-1 and 131-2.

The MRAM 100 of the present embodiment can reduce the influence of a difference in interconnect resistance according to the coordinates of the memory cell MC in the memory cell array 110 by using one of the nine selection methods based on the address ADR of the memory cell MC to be operated during the operation of the MRAM.

For example, in the present embodiment, the magnitude of the interconnect resistance applied to the memory cell MC is controlled by the operation of the switch circuits 121 and 131 such that the magnitude of the interconnect resistance applied to the memory cell MC existing in the region close to the switch circuit 121 and 131 becomes close to the magnitude of the interconnect resistance applied to the memory cell MC existing in the region far from the switch circuits 121 and 131.

### (a-6) Areas in Memory Cell Array

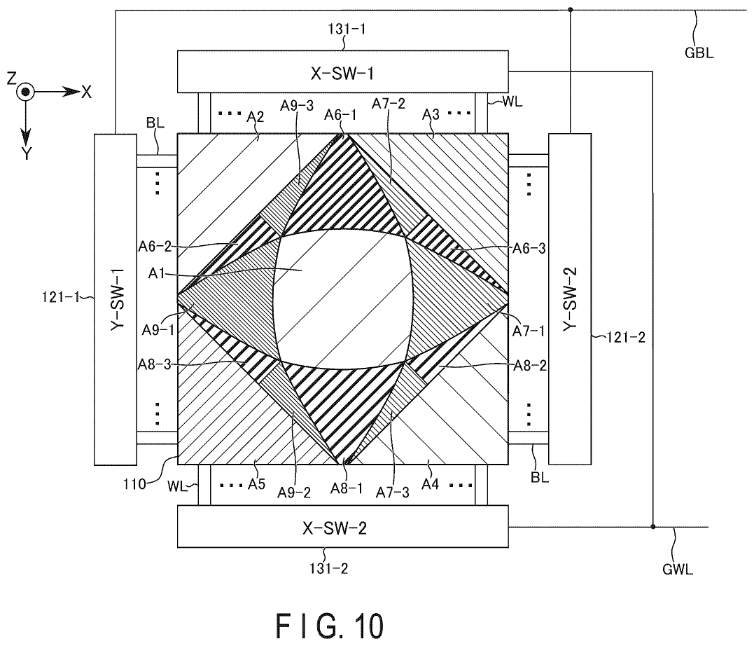

A plurality of areas set in the memory cell array 110 in the MRAM 100 of the present embodiment will be described with reference to FIG. 10.

The memory cell array 110 includes nine areas A1, A2, . . . , and A9 divided according to the nine selection methods (access methods) of memory cells in the memory cell array 110 by the column switch circuit 121 and the row switch circuit 131.

When the write operation or the read operation of the MRAM 100 is performed, any one of a plurality of selection methods of the memory cell MC by the column switch circuits 121-1 and 121-2 and the row switch circuits 131-1 and 131-2 is determined based on the address (coordinates) of the memory cell MC.

Here, in a case where the coordinates of the memory cell array 110 are associated with an azimuth, a side of the first row switch circuit 131-1 corresponds to the north direction, a side of the second row switch circuit 131-2 corresponds to the south direction, a side of the first column switch circuit 121-1 corresponds to the west direction, and a side of the second column switch circuit 121-2 corresponds to the east direction.

A first area A1 is a central region of the memory cell array 110.

The memory cell MC in the first area A1 is disposed at a position far from the voltage/current supply source with respect to the column of the memory cell array 110. For the distance between the memory cell MC and the two column switch circuits 121 in the X direction, the memory cell MC in the first area A1 is far from both of the two column switch circuits 121. The memory cell MC in the first area A1 is disposed at a position far from the voltage/current supply source with respect to the row of the memory cell array 110. For the distance between the memory cell MC and the two row switch circuits 131 in the Y direction, the memory cell MC in the first area A1 is far from both of the two row switch circuits 131.

The first area A1 is accessed by the two column switch circuits 121-1 and 121-2 in the ON state and the two row switch circuits 131-1 and 131-2 in the ON state.

As illustrated in (a) of FIG. 8, the memory cell MC in the first area A1 is electrically connected to the global bit line GBL by the two column switch circuits 121-1 and 121-2 in the ON state. As illustrated in (a) of FIG. 9, the memory cell MC in the first area A1 is electrically connected to the global word line GWL by the two row switch circuits 131-1 and 131-2 in the ON state.

A second area A2 is a region located in a northwest corner region of the memory cell array 110. The second area A2 is adjacent to the first column switch circuit 121-1 and the first row switch circuit 131-1.

The memory cell MC in the second area A2 is disposed at a position close to the voltage/current supply source with respect to the column of the memory cell array 110. For the distance between the memory cell MC and the two column switch circuits 121 in the X direction, the memory cell MC in the second area A2 is close to the first column switch circuit 121-1 and is far from the second column switch circuit 121-2. The memory cell MC in the second area A2 is disposed at a position close to the voltage/current supply source with respect to the row of the memory cell array 110. For the distance between the memory cell MC and the two row switch circuits 131 in the Y direction, the memory cell MC in the second area A2 is close to the first row switch circuit 131-1 and is far from the second row switch circuit 131-2.

The second area A2 is accessed by the first column switch circuit 121-1 in the ON state and the first row switch circuit 131-1 in the ON state.

As illustrated in (b) of FIG. 8, the memory cell MC in the second area A2 is connected to the global bit line GBL by the first column switch circuit 121-1 in the ON state. As illustrated in (b) of FIG. 9, the memory cell MC in the second area A2 is connected to the global word line GWL by the first row switch circuit 131-1 in the ON state.

In a case where the memory cell MC in the second area A2 is selected as an operation target, the second column switch circuit 121-2 and the second row switch circuit 131-2 are set to the OFF state.

A third area A3 is a region located in a northeast corner region of the memory cell array 110. The third area A3 is adjacent to the second column switch circuit 121-2 and the first row switch circuit 131-1.

The memory cell MC in the third area A3 is disposed at a position close to the voltage/current supply source with respect to the column of the memory cell array 110. For the distance between the memory cell MC and the two column switch circuits 121 in the X direction, the memory cell MC in the third area A3 is far from the first column switch circuit 121-1 and is close to the second column switch circuit 121-2. The memory cell MC in the third area A3 is disposed at a position close to the voltage/current supply source with respect to the row of the memory cell array 110. For the distance between the memory cell MC and the two row switch circuits 131 in the Y direction, the memory cell MC in the third area A3 is close to the first row switch circuit 131-1 and is far from the second row switch circuit 131-2.

The third area A3 is accessed by the second column switch circuit 121-2 in the ON state and the first row switch circuit 131-1 in the ON state.

As illustrated in (c) of FIG. 8, the memory cell MC in the third area A3 is connected to the global bit line GBL by the second column switch circuit 121-2 in the ON state. As illustrated in (b) of FIG. 9, the memory cell MC in the third area A3 is connected to the global word line GWL by the first row switch circuit 131-1 in the ON state.

In a case where the memory cell MC in the third area A3 is selected as an operation target, the first column switch circuit 121-1 and the second row switch circuit 131-2 are set to the OFF state.

A fourth area A4 is a region located in a southeast corner region of the memory cell array 110. The fourth area A4 is adjacent to the second column switch circuit 121-2 and the second row switch circuit 131-2.

The memory cell MC in the fourth area A4 is disposed at a position close to the voltage/current supply source with respect to the column of the memory cell array 110. For the distance between the memory cell MC and the two column switch circuits 121 in the X direction, the memory cell MC in the fourth area A4 is far from the first column switch circuit 121-1 and close to the second column switch circuit 121-2. The memory cell MC in the fourth area A4 is disposed at a position close to the voltage/current supply source with respect to the row of the memory cell array 110. For the distance between the memory cell MC and the two row switch circuits 131 in the Y direction, the memory cell MC in the fourth area A4 is far from the first row switch circuit 131-1 and close to the second row switch circuit 131-2.

The fourth area A4 is accessed by the second column switch circuit 121-2 in the ON state and the second row switch circuit 131-2 in the ON state.

As illustrated in (c) of FIG. 8, the memory cell MC in the fourth area A4 is connected to the global bit line GBL by the second column switch circuit 121-2 in the ON state. As illustrated in (c) of FIG. 9, the memory cell MC in the fourth area A4 is connected to the global word line GWL by the second row switch circuit 131-2 in the ON state.

In a case where the memory cell MC in the fourth area A4 is selected as an operation target, the first column switch circuit 121-1 and the first row switch circuit 131-1 are set to the OFF state.

A fifth area A5 is a region located in a southwest corner region of the memory cell array 110. The fifth area A5 is adjacent to the first column switch circuit 121-1 and the second row switch circuit 131-2.

The memory cell MC in the fifth area A5 is disposed at a position close to the voltage/current supply source with respect to the column of the memory cell array 110. For the distance between the memory cell MC and the two column switch circuits 121 in the X direction, the memory cell MC in the fifth area A5 is close to the first column switch circuit 121-1 and is far from the second column switch circuit 121-2. The memory cell MC in the fifth area A5 is disposed at a position close to the voltage/current supply source with respect to the row of the memory cell array 110. For the distance between the memory cell MC and the two row switch circuits 131 in the Y direction, the memory cell MC in the fifth area A5 is far from the first row switch circuit 131-1 and is close to the second row switch circuit 131-2.

The fifth area A5 is accessed by the first column switch circuit 121-1 in the ON state and the second row switch circuit 131-2 in the ON state.

As illustrated in (b) of FIG. 8, the memory cell MC in the fifth area A5 is connected to the global bit line GBL by the first column switch circuit 121-1 in the ON state. As illustrated in (c) of FIG. 9, the memory cell MC in the fifth area A5 is connected to the global word line GWL by the second row switch circuit 131-2 in the ON state.

In a case where the memory cell MC in the fifth area A5 is selected as an operation target, the second column switch circuit 121-2 and the first row switch circuit 131-1 are set to the OFF state.

A sixth area A6 (A6-1, A6-2, A6-3) is a region between the second area A2 and the third area A3, and is a region on a north side of the first area A1 (the side of the first row switch circuit 131-1). The sixth area A6 is surrounded by the first, second, and third areas A1, A2, and A3.

The sixth area A6 includes a region A6-1 between the first area A1 and the first row switch circuit 131-1, a region A6-2 between the second area A2 and a ninth area A9 (A9-1, A9-3) to be described later, and a region A6-3 between the third area A3 and a seventh area A7 (A7-1, A7-2) to be described later. The region A6-1 is surrounded by three areas A1, A2, and A3. The region A6-1 is adjacent to the first area A1 and regions A7-2 and A9-3 to be described later.

The sixth area A6 is accessed by the two column switch circuits 121-1 and 121-2 in the ON state and the first row switch circuit 131-1 in the ON state.

As illustrated in (a) of FIG. 8, the memory cell MC in the sixth area A6 is connected to the global bit line GBL via the first and second column switch circuits 121-1 and 121-2 in the ON state. As shown in (b) of FIG. 9, the memory cell MC in the sixth area A6 is connected to the global word line GWL via the first row switch circuit 131-1 in the ON state.

In a case where the memory cell MC in the sixth area A6 is selected as an operation target, the second row switch circuit 131-2 is set to the OFF state.

The seventh area A7 (A7-1, A7-2, A7-3) is a region between the third area A3 and the fourth area A4, and is a region on an east side of the first area A1 (the side of the second column switch circuit 121-2). The seventh area A7 is surrounded by the first, third, and fourth areas A1, A3, and A4.

The seventh area A7 includes a region A7-1 between the first area A1 and the second column switch circuit 121-2, a region A7-2 between the third area A3 and the sixth area A6 (A6-1, A6-2), and a region A7-3 between the fourth area A4 and an eighth area A8 (A8-1, A8-2) to be described later. The region A7-1 is surrounded by three areas A1, A3, and A4. The region A7-1 is adjacent to the first area A1, the region A6-3, and a region A8-2 to be described later.

The seventh area A7 is accessed by the second column switch circuit 121-2 in the ON state and the two row switch circuits 131-1 and 131-2 in the ON state.

As illustrated in (c) of FIG. 8, the memory cell MC in the seventh area A7 is connected to the global bit line GBL via the second column switch circuit 121-2 in the ON state. As illustrated in (a) of FIG. 9, the memory cell MC in the seventh area A7 is connected to the global word line GWL via the first and second row switch circuits 131-1 and 131-2 in the ON state.

In a case where the memory cell MC in the seventh area A7 is selected as an operation target, the first column switch circuit 121-1 is set to the OFF state.

The eighth area A8 is a region between the fourth area A4 and the fifth area A5, and is a region on a south side of the first area A1 (the side of the second row switch circuit 131-2). The eighth area A8 is surrounded by the first, fourth, and fifth areas A1, A4, and A5.

The eighth area A8 includes a region A8-1 between the first area A1 and the second row switch circuit 131-2, a region A8-2 between the fourth area A4 and the seventh area A7 (A7-1, A7-3), and a region A8-3 between the fifth area A5 and a ninth area A9 (A9-1, A9-2) to be described later. The region A8-1 is surrounded by three areas A1, A4, and A5. The region A8-1 is adjacent to the first area A1, the region A7-3, and a region A9-2 to be described later.

The eighth area A8 is accessed by the two column switch circuits 121-1 and 121-2 in the ON state and the second row switch circuit 131-2 in the ON state.

As illustrated in (a) of FIG. 8, the memory cell MC in the eighth area A8 is connected to the global bit line GBL via the first and second column switch circuits 121-1 and 121-2 in the ON state. As illustrated in (c) of FIG. 9, the memory cell MC in the eighth area A8 is connected to the global word line GWL via the second row switch circuit 131-2 in the ON state.

In a case where the memory cell MC in the eighth area A8 is selected as an operation target, the first row switch circuit 131-1 is set to the OFF state.

The ninth area A9 (A9-1, A9-2, A9-3) is a region between the second area A2 and the fifth area A5, and is a region on a west side of the first area A1 (the side of the first column switch circuit 121-1). The ninth area A9 is surrounded by the first, second, and fifth areas A1, A2, and A5.

The ninth area A9 includes a region A9-1 between the first area A1 and the first column switch circuit 121-1, the region A9-2 between the fifth area A5 and the eighth area A8 (A8-1, A8-3), and the region A9-3 between the second area A2 and the sixth area A6 (A6-1, A6-2). The region A9-1 is surrounded by three areas A1, A2, and A5. The region A9-1 is adjacent to the first area A1, the region A6-2, and the region A8-3.

The ninth area A9 is accessed by the first column switch circuit 121-1 in the ON state and the two row switch circuits 131-1 and 131-2 in the ON state.

As illustrated in (b) of FIG. 8, the memory cell MC in the ninth area A9 is connected to the global bit line GBL via the first column switch circuit 121-1 in the ON state. As illustrated in (a) of FIG. 9, the memory cell MC in the ninth area A9 is connected to the global word line GWL via the first and second row switch circuits 131-1 and 131-2 in the ON state.

In a case where the memory cell MC in the ninth area A9 is selected as an operation target, the second column switch circuit 121-2 is set to the OFF state.

As described above, in the MRAM 100 of the present embodiment, the nine areas A1, . . . , and A9 are set in the memory cell array 110.

As a tendency of the interconnect resistance applied to the memory cells MC in each area A1, . . . , and A9, the interconnect resistance applied to the memory cells MC in each area A6, A7, A8, and A9 is higher than the interconnect resistance applied to the memory cells MC in each area A2, A3, A4, and A5, and is lower than the interconnect resistance applied to the memory cell MC in the area A1.

In the present embodiment, the areas A1, . . . , and A9 including the memory cells MC to be operated are determined based on the address ADR provided to the MRAM 100. The column switch circuit 121 to be activated and the row switch circuit 131 to be activated are determined based on the determination results of the areas A1, . . . , and A9.

### (a-7) Conditions for Allocating Memory Cells in Each Area

The conditions under which each memory cell MC is allocated to each areas A1, . . . , and A9 described above will be described.

Here, in a case where the memory cell array 110 has a square array size, “M” is equal to “N”. Further, the magnitude of the resistance between the memory cells MC adjacent in the X direction is equal to the magnitude of the resistance between the memory cells MC adjacent in the Y direction.

The interconnect resistance between the memory cell MC and the global bit line GBL in the first area A1 is Rs×(x−0.5) (N−x+0.5)/N. The interconnect resistance between the memory cell MC and the global word line GWL in the first area A1 is Rs×(y−0.5) (N−y+0.5)/N.

The memory cell MC allocated to the first area A1 satisfy conditional expressions shown in the following (Expression 1a), (Expression 1b), (Expression 1c), and (Expression 1d).

$${( x - N )}^{2} + {( y - N / 2 )}^{2} \leq {N}^{2} / 2 \qquad ( Expression 1 a )$$

$${x}^{2} + {( y - N / 2 )}^{2} \leq {N}^{2} / 2 \qquad ( Expression 1 b )$$

$${( x - N / 2 )}^{2} + {( y - N )}^{2} \leq {N}^{2} / 2 \qquad ( Expression 1 c )$$

$${( x - N / 2 )}^{2} + {y}^{2} \leq {N}^{2} / 2 \qquad ( Expression 1 d )$$

The interconnect resistance between the memory cell MC and the global bit line GBL in the second area A2 is Rs×(x−0.5). The interconnect resistance between the memory cell MC and the global word line GWL in the second area A2 is Rs×(y−0.5).

The memory cell MC allocated to the second area A2 satisfy the conditional expression shown in the following (Expression 2).

$$x + y \leq N / 2 \qquad ( Expression 2 )$$

The interconnect resistance between the memory cell MC and the global bit line GBL in the third area A3 is Rs×(N−x+0.5). The interconnect resistance between the memory cell MC and the global word line GWL in the third area A3 is Rs×(y−0.5).

The memory cell MC allocated to the third area A3 satisfy the conditional expression shown in the following (Expression 3).

$$( N - x ) + y \leq N / 2 \qquad ( Expression 3 )$$

The interconnect resistance between the memory cell MC and the global bit line GBL in the fourth area A4 is Rs×(N−x+0.5). The interconnect resistance between the memory cell MC and the global word line GWL in the fourth area A4 is Rs×(N−y+0.5).

The memory cell MC allocated to the fourth area A4 satisfy the conditional expression shown in the following (Expression 4).

$$( N - x ) + ( N - y ) \leq N / 2 \qquad ( Expression 4 )$$

The interconnect resistance between the memory cell MC and the global bit line GBL in the fifth area A5 is Rs×(x−0.5). The interconnect resistance between the memory cell MC and the global word line GWL in the fifth area A5 is Rs×(N−y+0.5).

The memory cell MC allocated to the fifth area A5 satisfies the conditional expression shown in the following (Expression 5).

$$x + ( N - y ) \leq N / 2 \qquad ( Expression 5 )$$

The interconnect resistance between the memory cell MC and the global bit line GBL in the sixth area A6 is Rs×(x−0.5) (N−x+0.5)/N. The interconnect resistance between the memory cell MC and the global word line GWL in the sixth area A6 is Rs×(y−0.5).

The memory cell MC allocated to the sixth area A6 satisfy the conditional expressions shown in the following (Expression 6a), (Expression 6b), and (Expression 6c).

$${( x - N )}^{2} + {( y - N / 2 )}^{2} \geq {N}^{2} / 2 AND {( x - N / 2 )}^{2} + {( y - N )}^{2} \leq {N}^{2} / 2 AND {( x - N / 2 )}^{2} + {y}^{2} \leq {N}^{2} / 2 \qquad ( Expression 6 a )$$

$${( x - N )}^{2} + {( y - N / 2 )}^{2} \geq {N}^{2} / 2 AND x + y \geq N / 2 AND x + ( N - y ) \leq N \qquad ( Expression 6 b )$$

$${( x - N )}^{2} + {( y - N / 2 )}^{2} \geq {N}^{2} / 2 AND ( N - x ) + y \geq N / 2 AND ( N - x ) + ( N - y ) \leq N \qquad ( Expression 6 c )$$

The interconnect resistance between the memory cell MC and the global bit line GBL in the seventh area A7 is Rs×(N−x+0.5)/N. The interconnect resistance between the memory cell MC and the global word line GWL in the seventh area A7 is Rs×(y−0.5) (N−y+0.5)/N.

The memory cell MC allocated to the seventh area A7 satisfy the conditional expressions shown in the following (Expression 7a), (Expression 7b), and (Expression 7c).

$${x}^{2} + {( y - N )}^{2} \geq {N}^{2} / 2 AND {( x - N )}^{2} + {( y - N / 2 )}^{2} \leq {N}^{2} / 2 AND {x}^{2} + {( y - N / 2 )}^{2} \leq {N}^{2} / 2 \qquad ( Expression 7 a )$$

$${x}^{2} + {( y - N )}^{2} \geq {N}^{2} / 2 AND ( N - x ) + y \geq N / 2 AND x + y \leq N \qquad ( Expression 7 b )$$

$${x}^{2} + {( y - N )}^{2} \geq {N}^{2} / 2 AND ( N - x ) + ( N - y ) \geq N / 2 AND x + ( N - y ) \leq N \qquad ( Expression 7 c )$$

The interconnect resistance between the memory cell MC and the global bit line GBL in the eighth area A8 is Rs×(x−0.5) (N−x+0.5)/N. The interconnect resistance between the memory cell MC and the global word line GWL in the eighth area A8 is Rs×(N−y+0.5).

The memory cell MC allocated to the eighth area A8 satisfy the conditional expressions shown in the following (Expression 8a), (Expression 8b), and (Expression 8c).

$${x}^{2} + {( y - N / 2 )}^{2} \geq {N}^{2} / 2 AND {( x - N / 2 )}^{2} + {( y - N )}^{2} \leq {N}^{2} / 2 AND {( x - N / 2 )}^{2} + {y}^{2} \leq {N}^{2} / 2 \qquad ( Expression 8 a )$$

$${x}^{2} + {( y - N / 2 )}^{2} \geq {N}^{2} / 2 AND x + ( N - y ) \geq N / 2 AND x + y \leq N \qquad ( Expression 8 b )$$

$${x}^{2} + {( y - N / 2 )}^{2} \geq {N}^{2} / 2 AND ( N - x ) + ( N - y ) \geq N / 2 AND ( N - x ) + y \leq N \qquad ( Expression 8 c )$$

The interconnect resistance between the memory cell MC and the global bit line GBL in the ninth area A9 is Rs×(x−0.5). The interconnect resistance between the memory cell MC and the global word line GWL in the ninth area A9 is Rs×(y−0.5) (N−y+0.5).

The memory cell MC allocated to the ninth area A9 satisfy the conditional expressions shown in the following (Expression 9a), (Expression 9b), and (Expression 9c).

$${( x - N / 2 )}^{2} + {( y - N )}^{2} \geq {N}^{2} / 2 AND {( x - N )}^{2} + {( y - N / 2 )}^{2} \leq {N}^{2} / 2 AND {x}^{2} + {( y - N / 2 )}^{2} \leq {N}^{2} / 2 \qquad ( Expression 9 a )$$

$${( x - N / 2 )}^{2} + {( y - N )}^{2} \geq {N}^{2} / 2 AND x + y \geq N / 2 AND ( N - x ) + y \leq N \qquad ( Expression 9 b )$$

$${( x - N / 2 )}^{2} + {( y - N )}^{2} \geq {N}^{2} / 2 AND x + ( N - y ) \geq N / 2 AND ( N - x ) + ( N - y ) \leq N \qquad ( Expression 9 c )$$

As described above, the interconnect resistance applied to the memory cell MC (the interconnect resistance between the memory cell MC and the global interconnects GBL and GWL) depends on the coordinates of the memory cell MC in the memory cell array 110. Therefore, the memory cell MC can be allocated to the areas A1, A2, . . . , and A9 set in the memory cell array based on the coordinates of the memory cell MC in the memory cell array 110.

Note that, according to the coordinates (x, y) of the memory cell MC, the memory cell MC existing at a boundary (and near the boundary) between the plurality of areas A (A1 to A9) may conform to allocation conditions of the plurality of areas A. In this case, one memory cell MC can be allocated to a plurality of areas A. The memory cell existing at the boundary between the plurality of areas A may be allocated to any area A as long as the memory cell meets the allocation condition of each area A. It is preferable that the operation of the column switch circuit 121 and/or the operation of the row switch circuit 131 are designed such that the memory cell MC that exists at the boundary of the plurality of areas and conforms to the plurality of allocation conditions is allocated to any one of the areas A. As a result, a malfunction of the memory cell MC at the boundary between the plurality of areas A can be prevented.

### (b) Operation Example

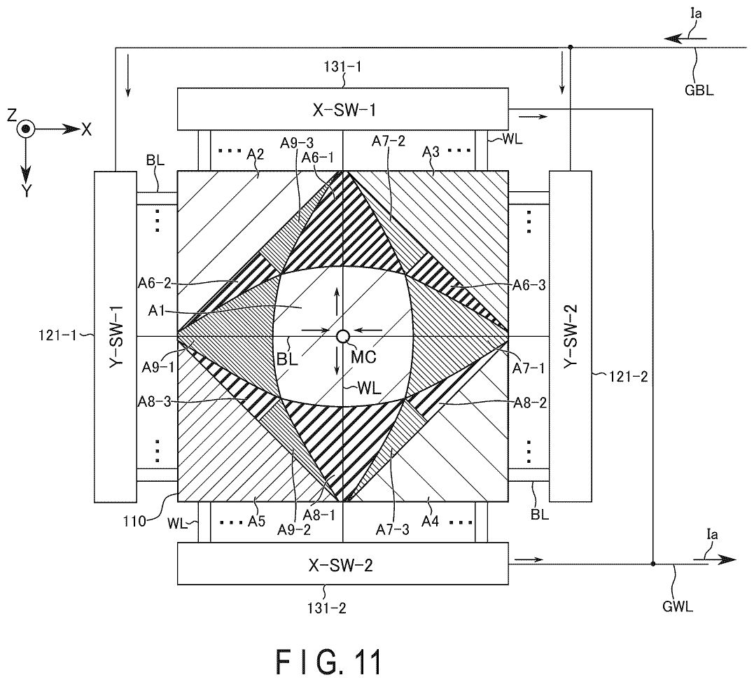

An operation example of the memory device (MRAM) 100 of the present embodiment will be described with reference to FIGS. 11 to 14.

The MRAM 100 of the present embodiment receives a command CMD, an address ADR, and various control signals CNT from the external device 900. In a case where the command CMD to be executed is a write operation, the MRAM 100 of the present embodiment further receives the write data DT from the external device 900.

The MRAM 100 of the present embodiment starts a commanded operation (a write operation or a read operation) based on the command CMD, the address ADR, and various control signals CNT.

The control circuit 180 performs various controls according to the operation to be executed based on the command CMD and various control signals CNT. The control circuit 180 decodes the address ADR.

The column control circuit 120 and the row control circuit 130 activate the column switch circuit 121 and the row switch circuit 131 based on the decoding result of the address ADR.

In the present embodiment, one or two column switch circuits 121-1 and 121-2 and one or two row switch circuits 131-1 and 131-2 are activated based on the coordinates (the address ADR) of the memory cell MC to be operated.

The memory cell (the selected cell) MC indicated by the address ADR is accessed by the activated one or two column switch circuits 121-1 and 121-2 and the activated one or two row switch circuits 131-1 and 131-2. The voltage and current used for the operation to be performed are supplied to the selected cell MC via the bit line BL and the word line WL.

FIG. 11 is a schematic diagram illustrating voltage and current supply paths in a case where the memory cell MC in the first area A1 is selected as an operation target. Note that, FIG. 11 illustrates an example in which current Ia flows from the global bit line GBL to the global word line GWL.

As illustrated in FIG. 11, in a case where the memory cell MC in the first area A1 is selected, the two column switch circuits 121-1 and 121-2 are set to the ON state, and the two row switch circuits 131-1 and 131-2 are set to the ON state.

The current Ia flows from the column switch circuit 121-1 to the selected cell MC via the resistance (the interconnect resistance) RX1 (=(x−0.5)×Rs), and from the column switch circuit 121-2 to the selected cell via the resistance (the interconnect resistance) RX2 (=(M−x+0.5)×Rs).

The current Ia flows from the selected cell MC to the row switch circuit 131-1 via the resistance (the interconnect resistance) RY1 (=(y−0.5)×Rs), and from the selected cell MC to the row switch circuit 131-2 via the resistance (the interconnect resistance) RY2 (=(N−y+0.5)×Rs).

In this way, in the write operation or the read operation of the MRAM 100, the voltage and current are supplied to the selected cell MC in the first area A1 via the two column switch circuits 121-1 and 121-2 and the two row switch circuits 131-1 and 131-2.

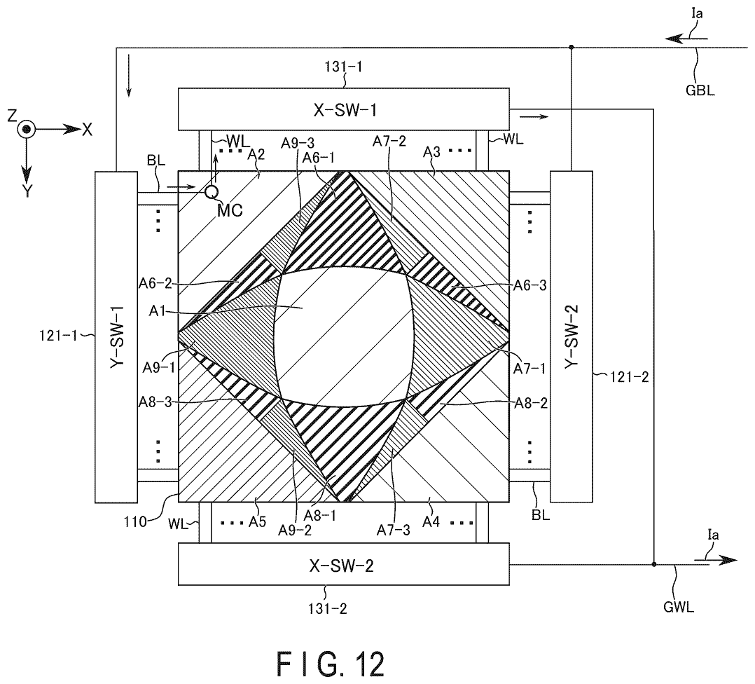

FIG. 12 is a schematic diagram illustrating voltage and current supply paths in a case where the memory cell MC in the second area A2 is selected as an operation target. Note that, FIG. 12 illustrates an example in which the current Ia flows from the global bit line GBL to the global word line GWL.

As illustrated in FIG. 12, in a case where the memory cell MC in the second area A2 is selected, one column switch circuit 121-1 is set to the ON state, and one row switch circuit 131-1 is set to the ON state.

The current Ia flows from the column switch circuit 121-1 to the selected cell MC via the resistance RX1.

The current Ia flows from the selected cell MC to the row switch circuit 131-1 via the resistance RY1.

In this way, in the write operation or the read operation of the MRAM 100, the voltage and current are supplied to the selected cell MC in the second area A2 via one column switch circuit 121-1 and one row switch circuit 131-1.

Similarly to the selected cells MC in the second area A2, the current Ia is also supplied to the selected cells MC in the third, fourth, and fifth areas A3, A4, and A5 via either one of the two column switch circuits 121 and either one of the two row switch circuits 131.

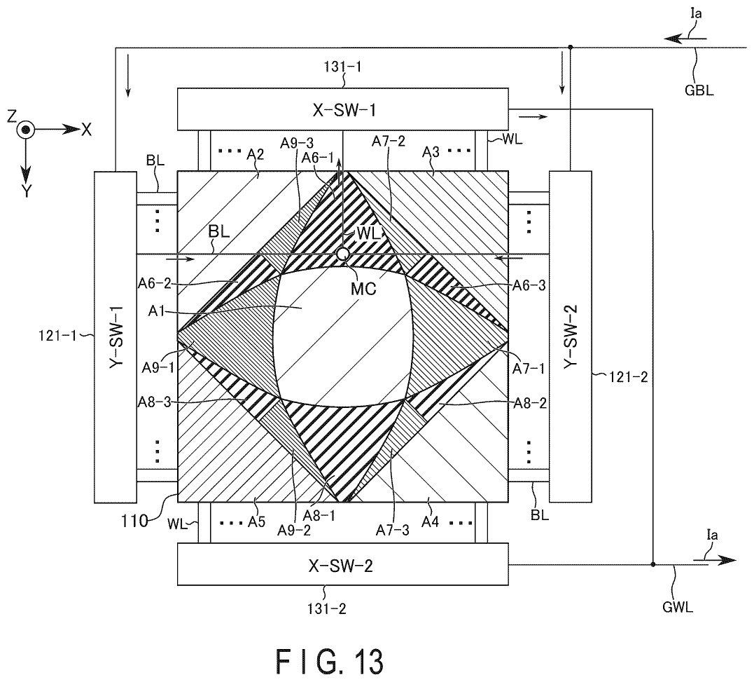

FIG. 13 is a schematic diagram illustrating voltage and current supply paths in a case where the memory cell MC in the sixth area A6 is selected as an operation target. Note that, FIG. 13 illustrates an example in which the current Ia flows from the global bit line GBL to the global word line GWL.

As illustrated in FIG. 13, in a case where the memory cell MC in the sixth area A6 is selected, the two column switch circuits 121-1 and 121-2 are set to the ON state, and one row switch circuit 131-1 is set to the ON state.

The current Ia flows from the column switch circuit 121-1 to the selected cell MC via the resistance RX1 and from the column switch circuit 121-2 to the selected cell MC via the resistance RX2.

The current Ia flows from the selected cell MC to the row switch circuit 131-1 via the resistance RY1.

In this way, in the write operation or the read operation of the MRAM 100, the voltage and current are supplied to the selected cell MC in the sixth area A6 via the two column switch circuits 121-1 and 121-2 and one row switch circuit 131-1.

The current Ia is also supplied to the selected cell MC in the eighth area A8 via the two column switch circuits 121-1 and 121-2 and one row switch circuit 131-2 substantially similarly to the selected cell MC in the sixth area A6.

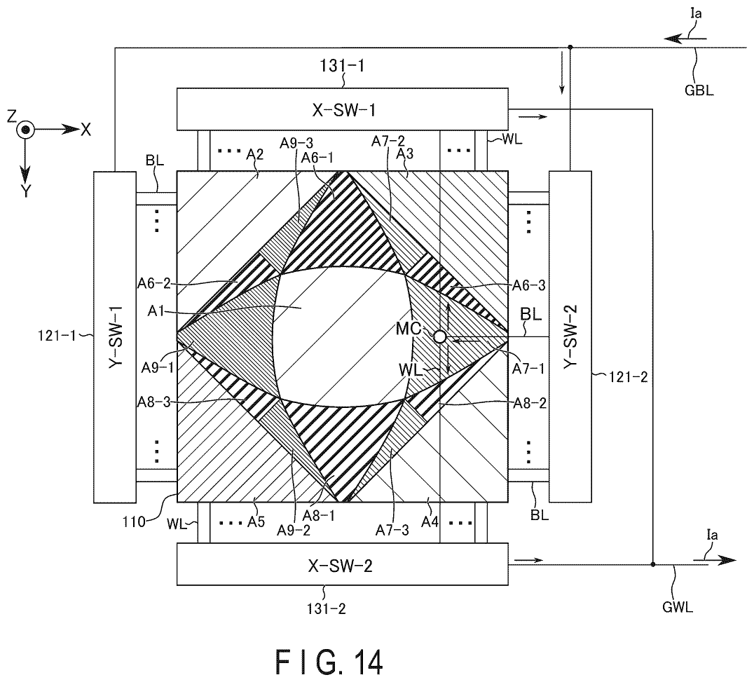

FIG. 14 is a schematic diagram illustrating voltage and current supply paths in a case where the memory cell MC in the seventh area A7 is selected as an operation target. Note that, FIG. 14 illustrates an example in which the current Ia flows from the global bit line GBL to the global word line GWL.

As illustrated in FIG. 14, in a case where the memory cell MC in the seventh area A7 is selected, one column switch circuit 121-2 is set to the ON state, and two row switch circuits 131-1 and 131-2 are set to the ON state.

The current Ia flows from the column switch circuit 121-2 to the selected cell MC via the resistance RX1.

The current Ia flows from the selected cell MC to the row switch circuit 131-1 via the resistance RY1 and from the selected cell MC to the row switch circuit 131-2 via the resistance RY2.

In this way, in the write operation or the read operation of the MRAM 100, the voltage and current are supplied to the selected cell MC in the seventh area A7 via one column switch circuit 121-2 and two row switch circuits 131-1 and 131-2.

The current Ia is also supplied to the selected cell MC in the ninth area A9 via one column switch circuit 121-1 and two row switch circuits 131-1 and 131-2 substantially similarly to the selected cell MC in the seventh area A7.

As described above, when various operations of the MRAM 100 of the present embodiment are performed, at least one of the two column switch circuits 121 and at least one of the two row switch circuits 131 are activated according to the coordinates of the memory cell MC corresponding to the supplied address ADR.

As a result, the MRAM 100 of the present embodiment can alleviate the influence of the difference in interconnect resistance applied to the memory cell MC due to the position of the memory cell MC in the memory cell array 110.

### (c) Experiment

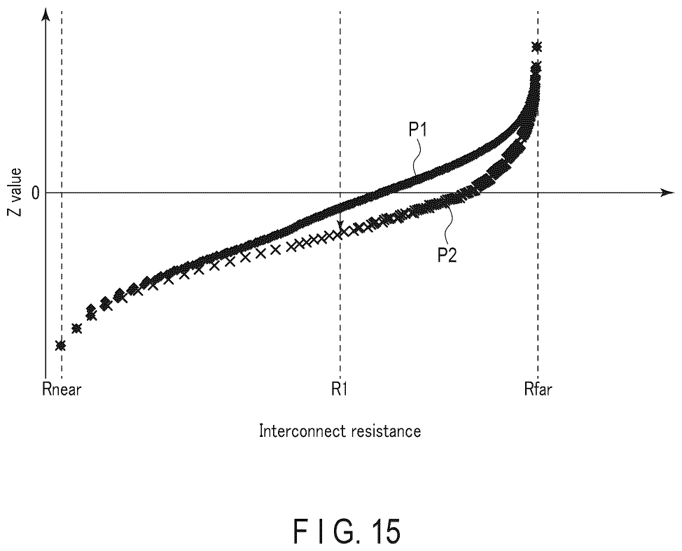

The characteristics of the MRAM 100 of the present embodiment will be described with reference to FIG. 15.

FIG. 15 is a graph illustrating results of an experiment on the MRAM 100 of the present embodiment.

A horizontal axis of the graph of FIG. 15 corresponds to the interconnect resistance applied to the memory cell. A vertical axis of the graph of FIG. 15 corresponds to the Z value regarding the malfunction.

In FIG. 15, a characteristic P1 including a set of square plots indicates experimental results of the MRAM of a comparative example, and a characteristic P2 including a set of cross-marked plots indicates the experimental results of the MRAM 100 of the present embodiment.

In the MRAM of the comparative example, two column switch circuits and two row switch circuits are activated to access the selected memory cell independently of the coordinates of the memory cell in the memory cell array.

In the example of FIG. 15, any of the memory cells MC in the first area A1 has the highest interconnect resistance Rfar. Any of the memory cells MC in the second to fifth areas A2, A3, A4, and A5 has the lowest interconnect resistance Rnear. Any of the memory cells MC in the sixth to ninth areas A6, A7, A8, and A9 has interconnect resistance R1.

As illustrated in FIG. 15, the Z value related to the malfunction of the MRAM 100 of the present embodiment is lower than the Z value related to the malfunction of the MRAM 100 of the comparative example.

For example, in the MRAM of the comparative example, 38% of memory cells having a resistance value equal to or less than the interconnect resistance R1 may cause a malfunction. On the other hand, in the MRAM 100 of the present embodiment, the number of memory cells that cause a malfunction among the memory cells having the resistance value equal to or less than the interconnect resistance R1 is 16%.

In this way, the MRAM 100 of the present embodiment can reduce a proportion of memory cells in which a malfunction may occur due to the coordinates (the interconnect resistance) of the memory cell.

### (d) Summary

In the MRAM 100 of the present embodiment, the memory cell array 110 includes the nine areas A1, . . . , and A9 set based on the coordinates of the memory cell MC.

The MRAM 100 of the present embodiment activates one or two of the two column switch circuits 121 and activates one or two of the two row switch circuits 131 according to the coordinates of the memory cell MC to be operated.

The bit line BL connected to the selected memory cell MC is connected to the global bit line GBL via one column switch circuit 121 or two column switch circuits 121 according to the coordinates of the memory cell MC. The word line WL connected to the selected memory cell MC is connected to the global word line GWL via one row switch circuit 131 or two row switch circuits 131 according to the coordinates of the memory cell MC.

As a result, the MRAM 100 of the present embodiment can reduce the difference in interconnect resistance applied to the memory cell MC due to the coordinates of the memory cell MC.

As a result, the MRAM 100 of the present embodiment can reduce the malfunction of the memory cell MC.

As described above, the memory device of the present embodiment can improve reliability.

### (2) Second Embodiment

A memory device according to a second embodiment will be described. Reference is made appropriately to FIGS. 1 to 14 in the description of the memory device of the present embodiment.

In a memory cell array 110 of a memory device such as an MRAM 100, the size of a column of the memory cell array 110 and the size of a row of the memory cell array 110 may be different.

In the memory cell array 110 of FIGS. 7 and 10 described above, in a case where the size of the column of the memory cell array 110 is different from the size of the row of the memory cell array 110, the value of “M” is different from the value of “N”. In this case, the memory cell array 110 has a rectangular layout when viewed from the Z direction.

Further, the magnitude of a resistance (Rs_X) between two memory cells MC adjacent in the X direction may be different from the magnitude of a resistance (Rs_Y) between two memory cells MC adjacent in the Y direction.

In the present embodiment, similarly to FIG. 7 described above, nine areas A1, . . . , and A9 are set in the memory cell array 110 in a rectangular shape according to the coordinates and interconnect resistance of the memory cell MC.

The following interconnect resistances are applied to the memory cells MC in the areas A1, . . . , and A9, respectively.

For the column in the first area A1, the interconnect resistance of Rs_x×M/((x−0.5) (M−x+0.5)) is applied to the memory cell MC in the first area A1 by two column switch circuits 121-1 and 121-2. For the row in the first area A1, the interconnect resistance of Rs_y×N/((y−0.5) (N−y+0.5)) is applied to the memory cell MC in the first area A1 by two row switch circuits 131-1 and 131-2.

For the column in the second area A2, the interconnect resistance of Rs_x×(x−0.5) is applied to the memory cell MC in the second area A2 by a first column switch circuit 121-1. For the row in the second area A2, the interconnect resistance of Rs_y×(y−0.5) is applied to the memory cell MC in the second area A2 by a first row switch circuit 131-1.

For the columns in the third area A3, the interconnect resistance of Rs_x×(M−x+0.5) is applied to the memory cell MC in the third area A3 by a second column switch circuit 121-2. For the row in the third area A3, the interconnect resistance of Rs_y×(y−0.5) is applied to the memory cell MC in the third area A3 by the first row switch circuit 131-1.

For the columns in the fourth area A4, the interconnect resistance of Rs_x×(M−x+0.5) is applied to the memory cell MC in the fourth area A4 by the second column switch circuit 121-2. For the row in the fourth area A4, the interconnect resistance of Rs_y×(N−y+0.5) is applied by a second row switch circuit 131-2.

For the columns in the fifth area A5, the interconnect resistance of Rs_x×(x−0.5) is applied to the memory cell MC in the fifth area A5 by the first column switch circuit 121-1. For the row in the fifth area A5, the interconnect resistance of Rs_y×(N−y+0.5) is applied to the memory cell MC in the fifth area A5 by the two row switch circuits 131-1 and 131-2.

For the column of the sixth area A6, the interconnect resistance of Rs_x×M/((x−0.5) (M−x+0.5)) is applied to the memory cell MC in the sixth area A6 by the two column switch circuits 121-1 and 121-2. For the row in the sixth area A6, the interconnect resistance of Rs_y×(y−0.5) is applied to the memory cell MC in the sixth area A6 by the first row switch circuit 131-1.

For the column of the seventh area A7, the interconnect resistance of Rs_x×(M−x+0.5) is applied to the memory cell MC in the seventh area A7 by the second column switch circuit 121-2. For the row in the seventh area A7, the interconnect resistance of Rs_y×N/((y−0.5) (N−y+0.5)) is applied to the memory cell MC in the seventh area A7 by the two row switch circuits 131-1 and 131-2.

For the column of the eighth area A8, the interconnect resistance of Rs_x×M/((x−0.5) (M−x+0.5)) is applied to the memory cell MC in the eighth area A8 by the two column switch circuits 121-1 and 121-2. For the row of the eighth area A8, the interconnect resistance of Rs_y×(N−y+0.5) is applied to the memory cell MC in the eighth area A8 by the second row switch circuit 131-2.

For the column of the ninth area A9, the interconnect resistance of Rs_x×(x−0.5) is applied to the memory cell MC in the ninth area A9 by the first column switch circuit 121-1. For the row in the ninth area A9, the interconnect resistance of Rs_y×N/((y−0.5) (N−y+0.5)) is applied to the memory cell MC in the ninth area A9 by the two row switch circuits 131-1 and 131-2.

As described above, the MRAM 100 of the present embodiment can reduce the difference in interconnect resistance according to the coordinates of the memory cell MC by controlling a column switch circuit 121 and a row switch circuit 131.

Therefore, the memory device of the present embodiment can obtain the same effects as those of the first embodiment.

### (3) Others

In the memory device 100 of the embodiments described above, nine areas A1, . . . , and A9 are set in the memory cell array 110. The number of areas set in the memory cell array 110 is not limited to nine. The number of areas set in the memory cell array 110 may be less than 9 or may be more than 9. For example, five areas can be set in the memory cell array 110 such that the areas are set in the center and four corner regions of the memory cell array 110 in a quadrangular shape.

In the embodiments described above, the MRAM is illustrated as the memory device 100 of the present embodiment. However, the memory device 100 of the present embodiment may be a memory device other than the MRAM.

For example, the memory device 100 of the present embodiment may be a memory device (for example, a resistance change memory such as a resistive random access memory (ReRAM)) that uses a transition metal oxide element having variable resistance characteristics as a memory element, a memory device (for example, a phase change memory such as a phase change random access memory (PCRAM)) that uses a phase change element as a memory element, or a memory device (for example, a ferroelectric memory such as a ferroelectric random access memory (FeRAM)) that uses a ferroelectric element as a memory element.

The memory device 100 of the present embodiment can obtain the effects described in the embodiments described above even if it is a memory device other than the MRAM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell array that including a plurality of bit lines, a plurality of word lines, and a plurality of memory cells respectively connected to one of the plurality of bit lines and one of the plurality of word lines, the memory cell array in which first to ninth areas are set;
a first column switch circuit connected to the plurality of bit lines and provided on one end side in a first direction of the memory cell array;
a second column switch circuit connected to the plurality of bit lines and provided on the other end side in the first direction of the memory cell array;
a first row switch circuit connected to the plurality of word lines and provided on one end side in a second direction of the memory cell array; and
a second row switch circuit connected to the plurality of word lines and provided on the other end side in the second direction of the memory cell array,
wherein
in a case where a memory cell in the first area is selected, the first and second column switch circuits and the first and second row switch circuits are activated, and
in a case where a memory cell in the second area is selected, the first column switch circuit and the first row switch circuit are activated, and
in a case where a memory cell in the third area is selected, the second column switch circuit and the first row switch circuit are activated, and
in a case where a memory cell in the fourth area is selected, the second column switch circuit and the second row switch circuit are activated, and
in a case where a memory cell in the fifth area is selected, the first column switch circuit and the second row switch circuit are activated, and
in a case where a memory cell in the sixth area is selected, the first and second column switch circuits and the first row switch circuit are activated, and
in a case where a memory cell in the seventh area is selected, the second column switch circuit and the first and second row switch circuits are activated, and
in a case where a memory cell in the eighth area is selected, the first and second column switch circuits and the second row switch circuit are activated, and
in a case where a memory cell in the ninth area is selected, the first column switch circuit and the first and second row switch circuits are activated.

2. The memory device according to claim 1, wherein
the memory cell array has a quadrangular layout, and
the first area is disposed in a central region of the memory cell array, and
the second area is disposed in a first corner region of the memory cell array, and
the third area is disposed in a second corner region of the memory cell array, and
the fourth area is disposed in a third corner region of the memory cell array, and
the fifth area is disposed in a fourth corner region of the memory cell array, and
the sixth area is disposed between the first, second, and third areas, and
the seventh area is disposed between the first, third, and fourth areas, and
the eighth area is disposed between the first, fourth, and fifth areas, and
the ninth area is disposed between the first, second, and fifth areas.

3. The memory device according to claim 2, wherein
the sixth area includes a first region, a second region, and a third region, and
the seventh area includes a fourth region, a fifth region, and a sixth region, and
the eighth area includes a seventh region, an eighth region, and a ninth region, and
the ninth area includes a tenth region, an eleventh region, and a twelfth region, and
the first region is provided between the first area, the second area, and the third area, and
the second region is provided between the second area and the tenth region, and
the third region is provided between the third area and the fourth region, and
the fourth region is provided between the first area, the third area, and the fourth area, and
the fifth region is provided between the third area and the first region, and
the sixth region is provided between the fourth area and the seventh region, and
the seventh region is provided between the first area, the fourth area, and the fifth area, and
the eighth region is provided between the fourth area and the fourth region, and
the ninth region is provided between the fifth area and the tenth region, and
the tenth region is provided between the first area, the second area, and the fifth area, and
the eleventh region is provided between the fifth area and the seventh region, and
the twelfth region is provided between the second area and the first region.

4. The memory device according to claim 1, further comprising:
a global bit line connected to the first and second column switch circuits; and
a global word line connected to the first and second row switch circuits.

5. The memory device according to claim 4, wherein
in a case where a memory cell of the sixth area is selected, the selected memory cell is connected to the global bit line via the first and second column switch circuits and is connected to the global word line via the first row switch circuit, and
in a case where a memory cell of the seventh area is selected, the selected memory cell is connected to the global bit line via the second column switch circuit and is connected to the global word line via the first and second row switch circuits, and
in a case where a memory cell of the eighth area is selected, the selected memory cell is connected to the global bit line via the first and second column switch circuits and is connected to the global word line via the second row switch circuit, and
in a case where a memory cell of the ninth area is selected, the selected memory cell is connected to the global bit line via the first column switch circuit and is connected to the global word line via the first and second row switch circuits.

6. The memory device according to claim 5, wherein
in a case where a memory cell in the first area is selected, the selected memory cell is connected to the global bit line via the first and second column switch circuits and is connected to the global word line via the first and second row switch circuits, and
in a case where a memory cell in the second area is selected, the selected memory cell is connected to the global bit line via the first column switch circuit and is connected to the global word line via the first row switch circuit, and
in a case where a memory cell in the third area is selected, the selected memory cell is connected to the global bit line via the second column switch circuit and is connected to the global word line via the first row switch circuit, and
in a case where a memory cell in the fourth area is selected, the selected memory cell is connected to the global bit line via the second column switch circuit and is connected to the global word line via the second row switch circuit, and
in a case where a memory cell in the fifth area is selected, the selected memory cell is connected to the global bit line via the first column switch circuit and is connected to the global word line via the second row switch circuit.

7. The memory device according to claim 1, wherein
interconnect resistance applied to each memory cell of the sixth, seventh, eighth, and ninth areas is higher than interconnect resistance applied to each memory cell of the second, third, fourth, and fifth areas, and is lower than interconnect resistance applied to a memory cell in the first area.

8. The memory device according to claim 1, wherein
one or both of the first and second column switch circuits are activated and one or both of the first and second row switch circuits are activated according to an address of a memory cell to be operated among the memory cells.

9. The memory device according to claim 1, wherein
each of the memory cells includes
a memory element, and
a switching element connected in series to the memory element.

10. The memory device according to claim 9, wherein
the memory element is a magnetoresistive effect element.

11. A memory device comprising:
a memory cell array including a plurality of bit lines, a plurality of word lines, and a plurality of memory cells respectively connected to one of the plurality of bit lines and one of the plurality of word lines, the memory cell array in which first to ninth areas are set;
a first column switch circuit connected to the plurality of bit lines and provided on one end side in a first direction of the memory cell array;
a second column switch circuit connected to the plurality of bit lines and provided on the other end side in the first direction of the memory cell array;
a first row switch circuit connected to the plurality of word lines and provided on one end side in a second direction of the memory cell array; and
a second row switch circuit connected to the plurality of word lines and provided on the other end side in the second direction of the memory cell array,
wherein
one or both of the first and second column switch circuits are activated and one or both of the first and second row switch circuits are activated according to an address of a memory cell to be operated among the memory cells.

12. The memory device according to claim 11, wherein
the memory cell array has a quadrangular layout, and
the first area is disposed in a central region of the memory cell array, and
the second area is disposed in a first corner region of the memory cell array, and
the third area is disposed in a second corner region of the memory cell array, and
the fourth area is disposed in a third corner region of the memory cell array, and
the fifth area is disposed in a fourth corner region of the memory cell array, and
the sixth area is disposed between the first, second, and third areas, and
the seventh area is disposed between the first, third, and fourth areas, and
the eighth area is disposed between the first, fourth, and fifth areas, and
the ninth area is disposed between the first, second, and fifth areas.

13. The memory device according to claim 12, wherein
the sixth area includes a first region, a second region, and a third region, and
the seventh area includes a fourth region, a fifth region, and a sixth region, and
the eighth area includes a seventh region, an eighth region, and a ninth region, and
the ninth area includes a tenth region, an eleventh region, and a twelfth region, and
the first region is provided between the first area, the second area, and the third area, and
the second region is provided between the second area and the tenth region, and
the third region is provided between the third area and the fourth region, and
the fourth region is provided between the first area, the third area, and the fourth area, and
the fifth region is provided between the third area and the first region, and
the sixth region is provided between the fourth area and the seventh region, and
the seventh region is provided between the first area, the fourth area, and the fifth area, and
the eighth region is provided between the fourth area and the fourth region, and
the ninth region is provided between the fifth area and the tenth region, and
the tenth region is provided between the first area, the second area, and the fifth area, and
the eleventh region is provided between the fifth area and the seventh region, and
the twelfth region is provided between the second area and the first region.

14. The memory device according to claim 11, further comprising:
a global bit line connected to the first and second column switch circuits; and
a global word line connected to the first and second row switch circuits.

15. The memory device according to claim 14, wherein
in a case where a memory cell of the sixth area is selected, the selected memory cell is connected to the global bit line via the first and second column switch circuits and is connected to the global word line via the first row switch circuit, and
in a case where a memory cell of the seventh area is selected, the selected memory cell is connected to the global bit line via the second column switch circuit and is connected to the global word line via the first and second row switch circuits, and
in a case where a memory cell of the eighth area is selected, the selected memory cell is connected to the global bit line via the first and second column switch circuits and is connected to the global word line via the second row switch circuit, and
in a case where a memory cell of the ninth area is selected, the selected memory cell is connected to the global bit line via the first column switch circuit and is connected to the global word line via the first and second row switch circuits.

16. The memory device according to claim 15, wherein
in a case where a memory cell in the first area is selected, the selected memory cell is connected to the global bit line via the first and second column switch circuits and is connected to the global word line via the first and second row switch circuits, and
in a case where a memory cell in the second area is selected, the selected memory cell is connected to the global bit line via the first column switch circuit and is connected to the global word line via the first row switch circuit, and
in a case where a memory cell in the third area is selected, the selected memory cell is connected to the global bit line via the second column switch circuit and is connected to the global word line via the first row switch circuit, and
in a case where a memory cell in the fourth area is selected, the selected memory cell is connected to the global bit line via the second column switch circuit and is connected to the global word line via the second row switch circuit, and
in a case where a memory cell in the fifth area is selected, the selected memory cell is connected to the global bit line via the first column switch circuit and is connected to the global word line via the second row switch circuit.

17. The memory device according to claim 11, wherein
interconnect resistance applied to each memory cell of the sixth, seventh, eighth, and ninth areas is higher than interconnect resistance applied to each memory cell of the second, third, fourth, and fifth areas, and is lower than interconnect resistance applied to a memory cell in the first area.

18. The memory device according to claim 11, wherein
each of the memory cells includes
a memory element, and
a switching element connected in series to the memory element.

19. The memory device according to claim 18, wherein
the memory element is a magnetoresistive effect element.
